(19) United States
(12) Patent Application Publication
(10) Pub. No.: US 2026/0096123 A1
(43) Pub. Date: Apr. 2, 2026

(54) SEMICONDUCTOR DEVICE

(71) Applicant: Samsung Electronics Co., Ltd., Suwon-si (KR)

(72) Inventors: June Young Park, Suwon-si (KR); HEONJONG SHIN, Suwon-si (KR); Seowoo Nam, Suwon-si (KR); SUNGGYU HAN, Suwon-si (KR)

(21) Appl. No.: 19/217,267

(22) Filed: May 23, 2025

(30) Foreign Application Priority Data
Sep. 30, 2024 (KR) 10-2024-0132837

(51) Int. Cl. H10D 30/01; H10D 30/00; H10D 62/00; H10D 62/13; H10D 64/01; H10D 64/23; H10D 64/62

(52) U.S. Cl. CPC H10D 30/0198; H10D 30/501; H10D 62/021; H10D 62/151; H10D 64/01; H10D 64/254; H10D 64/62

(57) ABSTRACT

A semiconductor device including a base insulation layer, a channel structure positioned on a first surface of the base insulation layer, a gate structure surrounding the channel structure, and a first source/drain pattern and a second source/drain pattern arranged spaced apart from each other along a first direction on both sides of the channel structure. The first and second source/drain patterns includes a liner layer and a filling layer on an inner surface of the liner layer, a portion of the lower and the side surfaces of the first source/drain pattern are covered by the base insulation layer. The liner layer includes a carbon-doped silicon germanium.

### CROSS-REFERENCE TO RELATED APPLICATION

This application claims priority 35 U.S.C. § 119 to and the benefit of Korean Patent Application No. 10-2024-0132837 filed in the Korean Intellectual Property Office on Sep. 30, 2024, the entire contents of which are incorporated herein by reference.

### BACKGROUND

### 1. Field

The present disclosure relates to a semiconductor device.

### 2. Description of the Related Art

Semiconductor devices are used in various electronic devices, such as storage devices that store data and processors that operate and process data. With the development of the electronic industry, various methods are being researched to improve various characteristics of the semiconductor devices such as integration, reliability, speed, and function. For example, semiconductor devices with 3-dimensional structure is being proposed to overcome the limitations caused by the reduction in the size of the semiconductor devices.

Recently, research is being conducted to improve congestion of routing, and scale the size of the semiconductor devices by placing an electric power network (a power delivery network) for routing signals provided to the semiconductor devices on the back of the substrate.

### SUMMARY

The task to be solved by the present disclosure is to provide a semiconductor device with improved reliability and a manufacturing method thereof.

The objects to be solved in the present disclosure are not limited to the above-mentioned objects, and other non-mentioned objects can be clearly understood to those skilled in the art from the following description.

A semiconductor device according to an embodiment includes a base insulation layer, a channel structure positioned on a first surface of the base insulation layer, a gate structure surrounding the channel structure, and a first source/drain pattern and a second source/drain pattern arranged spaced apart from each other along a first direction on both sides of the channel structure, wherein each of the first and second source/drain patterns includes a liner layer and a filling layer on an inner surface of the liner layer, a portion of the lower and the side surfaces of the first source/drain pattern are covered by the base insulation layer, and the liner layer includes a carbon-doped silicon germanium.

A semiconductor device according to an embodiment includes a base insulation layer including a first surface and a second surface facing the first surface, a channel structure positioned on the first surface of the base insulation layer, a gate structure surrounding the channel structure, a first source/drain pattern and a second source/drain pattern each positioned on both sides of the channel structure, the first source/drain pattern extending inside the base insulation layer, a lower wire structure positioned on the second surface of the base insulation layer, and a lower contact electrode connecting the second source/drain patterns and the lower wire structure, wherein the lower contact electrode includes a first contact region extending into the interior of the base insulation layer, and a second contact region extending from the upper surface of the first contact region into the interior of the second source/drain pattern, and the upper surface of the first contact region is positioned between the lower surface of the gate structure and the lower surface of the first source/drain pattern.

A semiconductor device according to an embodiment includes a base insulation layer, a channel structure positioned above the base insulation layer, a gate structure surrounding the channel structure, source/drain patterns including a first source/drain pattern and a second source/drain pattern positioned on both sides of the channel structure, a lower wire structure positioned above the lower surface of the base insulation layer, and a lower contact electrode connecting the second source/drain pattern and the lower wire structure, an upper wire structure positioned above the source/drain patterns, and an upper contact electrode connecting the first source/drain pattern and the upper wire structure, wherein the lower contact electrode includes a first contact region extending into the interior of the base insulation layer, and a second contact region extending from the upper surface of the first contact region into the interior of the second source/drain pattern, and the upper surface of the first contact region is positioned between the lower surface of the gate structure and the lower surface of the first source/drain pattern.

The semiconductor device according to the embodiment may have the first and second source/drain patterns formed deeply in the downward direction of a substrate, and may include a region doped with carbon (C) or boron (B) in the region adjacent to the side surface and the lower surface within the source/drain pattern.

According to embodiments, in a process of etching the back surface of the substrate to form a back-side power delivery network, the source/drain patterns may be protected from an etching material, thereby improving the reliability of the semiconductor device.

### BRIEF DESCRIPTION OF THE DRAWINGS

FIG. 1 is a top plan view showing a semiconductor device according to an embodiment.

FIG. 2 is a cross-sectional view of a semiconductor device along a line I1-I1′ of FIG. 1.

FIG. 3 is a cross-sectional view of a semiconductor device along a line I2-I2′ of FIG. 1.

FIG. 4 is a cross-sectional view of a semiconductor device along a line I3-I3′ of FIG. 1.

FIG. 5 is a cross-sectional view of a semiconductor device along a line I4-I4′ of FIG. 1.

FIG. 6 is a cross-sectional view showing a semiconductor device according to an embodiment.

FIG. 7 is a cross-sectional view showing a semiconductor device according to an embodiment.

FIG. 8 to FIG. 32 are process cross-sectional views for explaining a manufacturing method of a semiconductor device according to an embodiment.

### DETAILED DESCRIPTION

The present disclosure will be described more fully hereinafter with reference to the accompanying drawings, in which exemplary embodiments of the disclosure are shown. As those skilled in the art would realize, the described embodiments may be modified in various different ways, all without departing from the spirit or scope of the present disclosure.

Descriptions of parts not related to the present disclosure are omitted, and like reference numerals designate like elements throughout the specification.

Further, since sizes and thicknesses of constituent members shown in the accompanying drawings are arbitrarily given for better understanding and ease of description, the present disclosure is not limited to the illustrated sizes and thicknesses. In the drawings, the thickness of layers, films, panels, regions, etc., are exaggerated for clarity. In the drawings, for better understanding and ease of description, the thicknesses of some layers and areas are exaggerated.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction. When an element is referred to as being “directly connected” or “directly coupled” to another element, or as “contacting,” “in contact with,” or “contact” another element, there are no intervening elements present at the point of contact.

In addition, unless explicitly described to the contrary, the word “comprise”, and variations such as “comprises” or “comprising,” will be understood to imply the inclusion of stated elements but not the exclusion of any other elements. Throughout the specification, when a component is described as “including” a particular element or group of elements, it is to be understood that the component is formed of only the element or the group of elements, or the element or group of elements may be combined with additional elements to form the component, unless the context clearly and/or explicitly describes the contrary. The term “consisting of,” on the other hand, indicates that a component is formed only of the element(s) listed.

Further, in the specification, the phrase “on a plane” means when an object portion is viewed from above, and the phrase “on a cross-section” means when a cross-section taken by vertically cutting an object portion is viewed from the side.

In drawings of a semiconductor device according to an embodiment, GAA (Gate All Around) and MBCFET™ (Multi-Bridge Channel Field Effect Transistor) including nano wires or nano sheets are illustrated as examples, but are not limited thereto. According to the embodiment, the semiconductor device may include a fin-type transistor (FinFET) including a channel structure in a fin-type pattern shape, a tunneling transistor (tunneling FET), a 3D-SFET (3D Stack Field Effect Transistor) structure, and a CFET (Complementary Field Effect Transistor) structure.

Below, a semiconductor device according to an embodiment is described with reference to accompanying drawings.

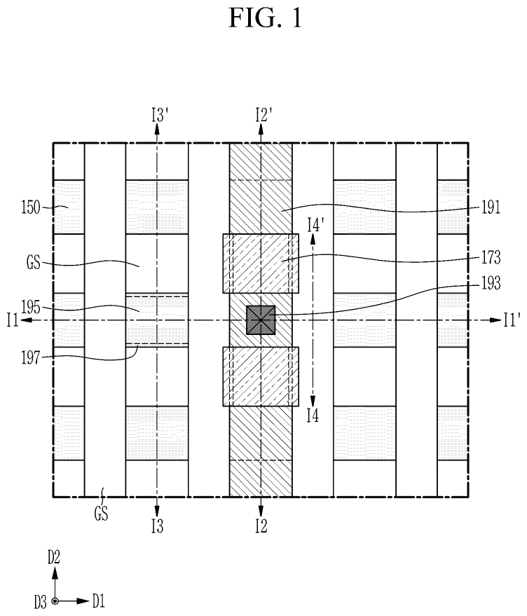

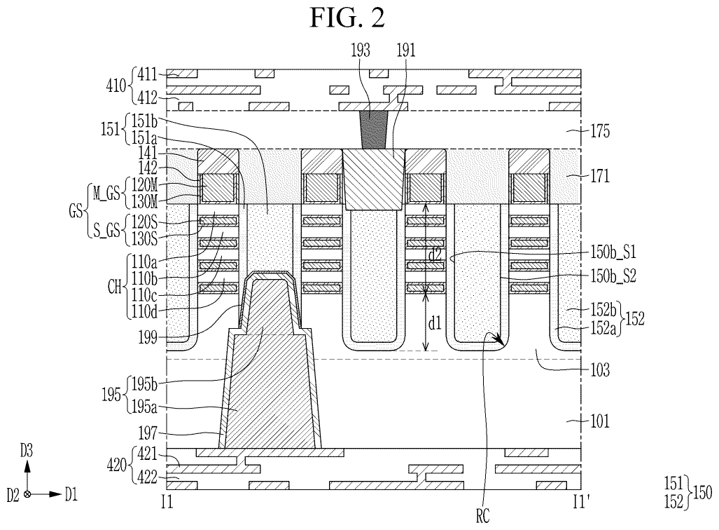

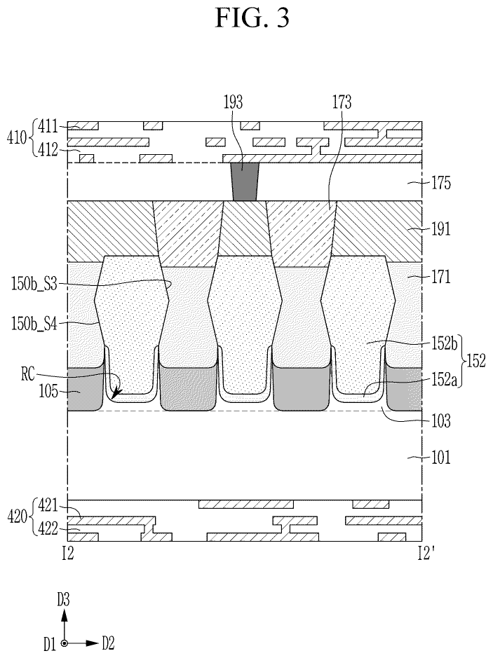

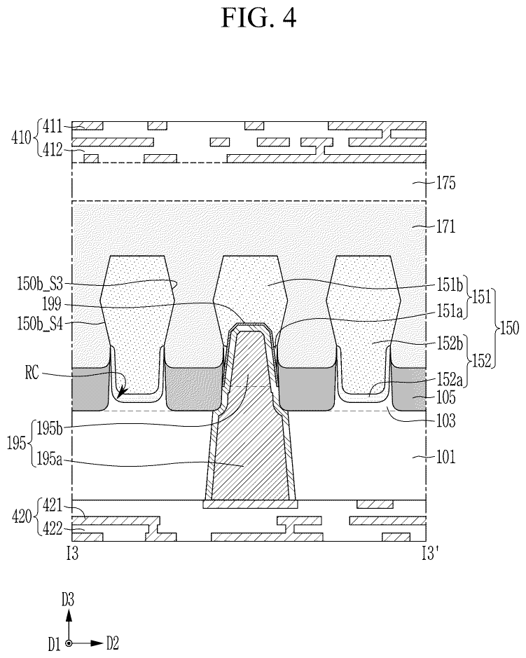

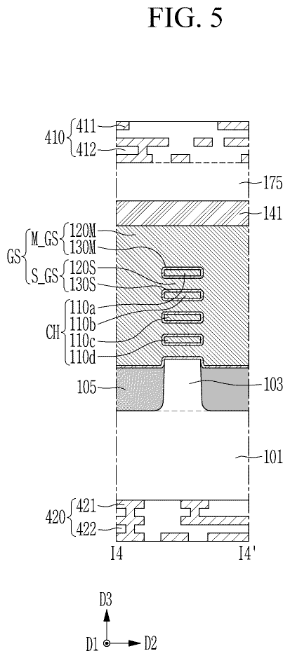

FIG. 1 is a top plan view showing a semiconductor device according to an embodiment. FIG. 2 to FIG. 4 are cross-sectional views showing a semiconductor device according to an embodiment. In detail, FIG. 2 is a cross-sectional view of a semiconductor device along a line I1-I1′ of FIG. 1. FIG. 3 is a cross-sectional view of a semiconductor device along a line I2-I2′ of FIG. 1. FIG. 4 is a cross-sectional view of a semiconductor device along a line I3-I3′ of FIG. 1. FIG. 5 is a cross-sectional view of a semiconductor device along a line I4-I4′ of FIG. 1.

Referring to FIG. 1 to FIG. 5, a semiconductor device according to an embodiment may include a base insulation layer 101, a channel structures CH positioned on the base insulation layer 101, a gate structure GS surrounding the channel structures CH, and a source/drain patterns 150 positioned on both sides of each channel structure CH.

The base insulation layer 101 may be an insulation substrate. The base insulation layer 101 may include an oxide, a nitride, a nitrite or a combination thereof. For example, the base insulation layer 101 may include silicon oxide (SiO₂). The base insulation layer 101 is illustrated as a single layer, but this is only for better understanding and ease of description and is not limited thereto. The base insulation layer 101 may be formed by filling an etched portion with an insulating material after a substrate 10 (referring to FIG. 5) described below is etched. In an embodiment, the base insulation layer 101 may include an insulating material having an etch selectivity from a source/drain pattern 150 as described below.

In FIG. 2 to FIG. 5, the base insulation layer 101 is shown as being a single layer, but the base insulation layer 101 may be composed of two or more layers. In this case, two or more layers may include different insulating materials or may include the same insulating material.

The base insulation layer 101 may include a first surface and a second surface facing each other. The first surface and the second surface of the base insulation layer 101 may be formed of a plane parallel to a first direction D1 and a second direction D2 intersecting the first direction D1. For example, the first surface of the base insulation layer 101 may be the upper surface, and the second surface may be the lower surface. The upper surface of the base insulation layer 101 is a surface opposite to the lower surface of the base insulation layer 101 in a third direction D3. The third direction D3 may be a direction perpendicular to the first direction D1 and the second direction D2. The lower surface of the base insulation layer 101 may be referred to as the back side of the base insulation layer 101. In some embodiments, a logic circuit of a cell region may be implemented on the upper surface of the base insulation layer 101.

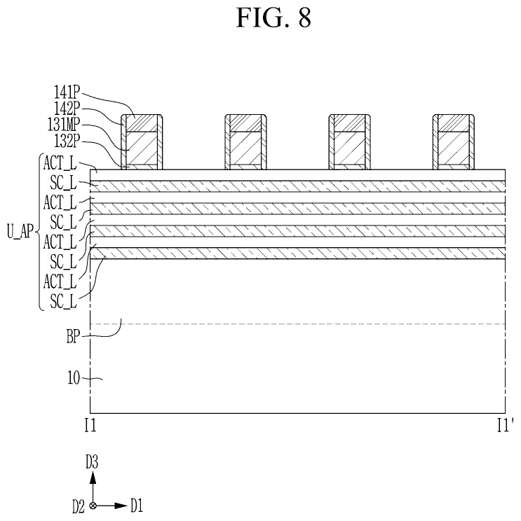

The base insulation layer 101 may include protruded regions 103 that protrude from the first surface. The protruded regions 103 may be portions that protrude in the third direction D3 from the upper surface of the base insulation layer 101. The protruded regions 103 may be formed as an etched portion is filled with an insulating material after a lower pattern (BP, referring to FIG. 8) described below is etched.

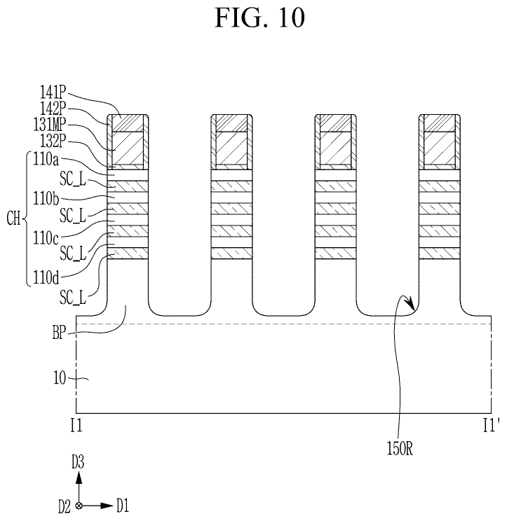

In an embodiment, the protruded region 103 may include a recess region RC formed in a direction toward the upper surface of the base insulation layer 101. The recess region RC may be formed by deeply recessing the lower pattern (BP, referring to FIG. 10) to a portion adjacent to the upper surface of the base insulation layer 101 in a source/drain recess (150R, referring to FIG. 10) forming process described later. The remaining lower pattern BP region that is not recessed may then be replaced with an insulating material to form the protruded region 103.

The width of the recess region RC may become narrower as it approaches the upper surface of the base insulation layer 101. The bottom surface of the recess region RC may be positioned at a higher level than the upper surface of the base insulation layer 101.

The source/drain pattern 150 described later may be positioned inside the recess region RC. The source/drain pattern 150 may include at least some regions surrounded by the protruded region 103. Some regions of the source/drain pattern 150 positioned at a level lower than the upper surface of the protruded region 103 may be surrounded by the protruded region 103.

Referring to FIG. 3 and FIG. 4, the protruded regions 103 may be arranged spaced apart from each other in the second direction D2 on the upper surface of the base insulation layer 101. Referring to FIG. 2, each of the protruded regions 103 may be extended in the first direction D1. The source/drain patterns 150 may be arranged spaced apart from each other in the first direction D1 on each of the protruded regions 103.

The protruded regions 103 may include an insulating material. The protruded regions 103 may include silicon oxide SiO₂, silicon nitride(SiN_{X}), silicon oxynitride(SiON) or combination thereof. In the embodiment, the protruded region 103 and the remaining region of the base insulation layer 101 may be formed integrally. In this case, the boundary between the protruded region 103 and the remaining region of the base insulation layer 101 may not be visible.

The channel structures CH may be positioned on the upper surface of the base insulation layer 101. As shown in FIG. 2 and FIG. 3, the channel structures CH may be positioned over the protruded region 103. The channel structures CH may be arranged spaced apart in the first direction D1 on the protruded region 103. Each channel structure CH may include a first channel pattern 110a, a second channel pattern 110b, a third channel pattern 110c, and a fourth channel pattern 110d. The plurality of channel patterns 110a, 110b, 110c, and 110d may be arranged spaced apart from each other in the third direction D3. For example, each of the plurality of channel patterns 110a, 110b, 110c, and 110d may have a sheet shape. Each channel pattern 110a, 110b, 110c, and 110d can be a nano sheet with a thickness of several nanometers along the third direction D3.

The channel structure CH may provide a passage for a current to flow between the source/drain patterns 150, as described below. Referring to FIG. 2, the channel structure CH may be arranged between the source/drain patterns 150, so that it may connect the source/drain patterns 150. The channel structures CH may penetrate a part of the gate structure GS in a direction (e.g., the first direction D1) that intersects the direction in which the gate structure GS extends, which will be described later. In FIG. 2, the channel structures CH are illustrated as having four channel patterns 110a, 110b, 110c, and 110d arranged spaced apart in the third direction D3, but are not limited thereto, and the number of stacks of the channel patterns 110a, 110b, 110c, and 110d included in one channel structure CH may vary.

The channel structures CH may include a semiconductor material. For example, the channel structures CH may include Group IV semiconductors such as Si, Ge, Group III-V compound semiconductors, Group II-VI compound semiconductors, etc. In the embodiment, the protruded region 103 may be positioned at the lower part of the channel structure CH. The protruded region 103 may be positioned between a sub-gate structure S_GS positioned at the lowest position among a plurality of sub-gate structures S_GS described below and the upper surface of the base insulation layer 101. In the embodiment, the channel structure CH may overlap the protruded region 103 in the third direction D3. At least some regions of the upper surface of the protruded region 103 may be in contact with the lower surface of the sub-gate structure S_GS, which is positioned at the lowest position among the plurality of sub-gate structures S_GS. In the embodiment, the recess RC formed in the protruded region 103 may not overlap the channel structure CH in the third direction D3.

Referring to FIG. 2 and FIG. 3, the semiconductor device according to the embodiment may further include a field insulation layer 105 positioned over the base insulation layer 101. The field insulation layer 105 may be positioned between two protruded regions 103 adjacent in the second direction D2. The field insulation layer 105 may not be positioned on the upper surface of the protruded region 103.

The field insulation layer 105 may be positioned over the upper surface of the base insulation layer 101 and the side surfaces of the protruded regions 103. The field insulation layer 105 may be positioned on both sides of the protruded region 103. The field insulation layer 105 may completely cover the side of the protruded region 103. Unlike what is shown, the field insulation layer 105 may also cover a part of the side of the protruded region 103. In such a case, a part of the protruded region 103 may protrude further in the third direction D3 than the upper surface of the field insulation layer 105. In the embodiment, the field insulation layer 105 may include a region that overlaps a portion of the source/drain pattern 150 described below in the second direction D2. Specifically, in the embodiment, the source/drain pattern 150 may also be positioned within the recess region RC inside the protruded region 103, and some regions of the source/drain pattern 150 positioned within the recess region RC may overlap the field insulation layer 105 in the second direction D2. In the region positioned at the level lower than the bottom surface of the gate structure GS to be described later, filling layers 151b and 152b may be positioned between a field insulation layer 105 and liner layers 151a and 152a.

The field insulation layer 105 may include, for example, oxide, nitride, oxynitride or combination layers thereof. The field insulation layer 105 is illustrated as a single film, but this is only for better understanding and ease of description and is not limited thereto.

The gate structure GS may be positioned on the base insulation layer 101. A protruded region 103 or a field insulation layer 105 may be positioned between the gate structure GS and the upper surface of the base insulation layer 101. The gate structure GS may extend in a direction different from the direction in which the protruded region 103 extends on the base insulation layer 101. For example, the gate structure GS may extend on the base insulation layer 101 in a direction (e.g., the second direction D2) intersecting the direction in which the protruded region 103 extends. The gate structure GS may be positioned on the base insulation layer 101. The gate structures GS may be arranged spaced apart from each other in the first direction D1. The gate structure GS may include a sub-gate structure S_GS and a main gate structure M_GS. The sub-gate structure S_GS may be positioned on the base insulation layer 101, and the main gate structure M_GS may be positioned on the sub-gate structure S_GS.

Each of the sub-gate structures S_GS may consist of multiple layers. For example, each of the sub-gate structures S_GS may include a sub-gate electrode 120S and a sub-gate insulation layer 130S. The sub-gate structures S_GS and the channel patterns 110a, 110b, 110c, and 110d may be alternately stacked in the third direction D3. In FIG. 2, four sub-gate structures S_GS are depicted as arranged spaced apart in the third direction D3, but the number of the sub-gate structures S_GS arranged spaced apart is not limited to this. For example, the gate structure GS may include three sub-gate structures S_GS.

The sub-gate electrode 120S may be positioned over the protruded region 103. Above the protruded region 103, the plurality of sub-gate electrodes 120S may be positioned spaced apart from each other. The plurality of sub-gate electrodes 120S and the plurality of channel patterns 110a, 110b, 110c, and 110d can be alternately and repeatedly stacked. At least one of the upper and lower surfaces of the plurality of channel patterns 110a, 110b, 110c, and 110d may be covered by the sub-gate electrode 120S. For example, the lower surface of the first channel pattern 110a may be covered by the sub-gate electrode 120S, and the upper surface of the fourth channel pattern 110d may be covered by the sub-gate electrode 120S. The upper and lower surfaces of each of the second channel pattern 110b and the third channel pattern 110c may be covered by the sub-gate electrode 120S.

The sub-gate electrode 120S may include at least one of a metal, a metal alloy, a conductive metal nitride, a metal silicide, a doped semiconductor material, a conductive metal oxide, and a conductive metal oxynitride. The sub-gate electrode 120S, for example, may include at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonization nitride (TiAlC—N), titanium aluminum carbide (TiAlC), titanium carbide (TiC), tantalum carbonization nitride (TaCN), tungsten (W), aluminum (Al), copper (Cu), cobalt (Co), titanium (Ti), tantalum (Ta), nickel (Ni), platinum (Pt), nickel platinum (Ni-Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and combinations thereof, but it is not limited thereto. The conductive metal oxide and the conductive metal oxynitride may include an oxidized form of the material described above, but are not limited thereto.

The sub-gate insulation layer 130S may be positioned along the circumference of the plurality of channel patterns 110a, 110b, 110c, and 110d. The sub-gate insulation layer 130S may be interposed between the plurality of channel patterns 110a, 110b, 110c, and 110d and the sub-gate electrode 120S. The sub-gate insulation layer 130S may include various insulating materials. Although not explicitly disclosed in FIG. 2, the semiconductor device according to the embodiment may further include an inner gate spacer positioned between the sub-gate insulation layer 130S and the source/drain pattern 150 described below.

In an embodiment, the sub-gate insulation layer 130S is depicted as a single film, but is not limited thereto. For example, the sub-gate insulation layer 130S may be composed of a multilayer including silicon oxide (SiO₂) and a high dielectric constant material. At this time, the high dielectric constant material may include a material with a higher dielectric constant than silicon oxide (SiO₂), such as hafnium oxide (HfO), aluminum oxide (AlO), or tantalum oxide (TaO).

The main gate structure M_GS may be positioned on the sub-gate structure S_GS and the plurality of channel patterns 110a, 110b, 110c, and 110d. The main gate structure M_GS may be positioned on the upper surface of the channel pattern 110a, which is positioned at the uppermost position among the plurality of channel patterns 110a, 110b, 110c, and 110d. Referring to FIG. 5, the main gate structure M_GS may also be positioned on the field insulation layer 105. The main gate structure M_GS may cover both lateral sides of the sub-gate structure S_GS.

The main gate structure M_GS may include a main gate electrode 120M and a main gate insulation layer 130M.

The main gate electrode 120M may be positioned on the sub-gate structure S_GS and the plurality of channel patterns 110a, 110b, 110c, and 110d. The main gate electrode 120M may be extended in a direction intersecting with the protruded region 103. At least a portion of the main gate electrode 120M may be positioned on a structure in which the sub-gate electrode 120S and the plurality of channel patterns 110a, 110b, 110c, and 110d are alternately stacked. The remaining part of the main gate electrode 120M may cover the side of the structure in which the sub-gate electrode 120S and the plurality of channel patterns 110a, 110b, 110c, and 110d are alternately stacked. Four surfaces of each of the plurality of channel patterns 110a, 110b, 110c, and 110d may be surrounded by the sub-gate electrodes 120S and/or the main gate electrodes 120M.

The main gate electrode 120M may include the same material as the sub-gate electrode 120S. For example, the main gate electrode 120M may include at least one of a metal, a metal alloy, a conductive metal nitride, a metal silicide, a doped semiconductor material, a conductive metal oxide, and a conductive metal oxynitride.

The main gate insulation layer 130M may extend along the side of the main gate electrode 120M. The main gate insulation layer 130M may extend along a side of a gate spacer 142 described below. The main gate insulation layer 130M may include various insulating materials. The main gate insulation layer 130M may include the same material as the sub-gate insulation layer 130S.

In an embodiment, the main gate insulation layer 130M is depicted as a single film, but is not limited thereto. For example, the main gate insulation layer 130M may be composed of a multilayer including silicon oxide (SiO₂) and a high dielectric constant material. At this time, the high dielectric constant material may include a material with a higher dielectric constant than silicon oxide (SiO₂), such as hafnium oxide (HfO), aluminum oxide (AlO), or tantalum oxide (TaO).

The semiconductor device according to the embodiment may further include a capping layer 141 and a gate spacer 142.

The gate spacer 142 may be positioned on the side of the main gate electrode 120M. The gate spacer 142 may be positioned on the channel structure CH. The gate spacer 142 may not be positioned on the side of the sub-gate electrode 120S. The gate spacer 142 may not be positioned on each side of the channel patterns 110a, 110b, 110c, and 110d. The gate spacer 142 may not be placed between the protruded region 103 and the plurality of channel patterns 110a, 110b, 110c, and 110d. The gate spacer 142 may not be placed between the plurality of channel patterns 110a, 110b, 110c, and 110d adjacent in the third direction D3. The gate spacer 142 is shown as a single layer, but this is for better understanding and ease of description and is not intended to be limiting.

The gate spacer 142, for example, may include at least one of silicon nitride (SiN_{X}), silicon oxynitride (SiON), silicon oxide (SiO₂), silicon carbonate nitride (SiOCN), silicon boron nitride (SiBN), silicon boron oxynitride (SiOBN), silicon oxycarbide (SiOC), and combinations thereof. The gate spacer 142 is shown as being a single layer, but for better understanding and ease of description and this is not intended to be limiting.

The capping layer 141 may be positioned on the main gate structure M_GS and gate spacer 142. The upper and side surfaces of the capping layer 141 may be covered by a first interlayer insulation layer 171, which will be described later. Unlike what is shown, the capping layer 141 may also be positioned between the gate spacers 142.

The capping layer 141 may include, for example, at least one of silicon nitride (SiN), silicon oxynitride (SiON), silicon (Si) carbonization nitride (SiCN), silicon carbonate nitride (SiOCN), and a combination thereof. The capping layer 141 may include a material having an etch selectivity from the first interlayer insulation layer 171 described below.

The source/drain patterns 150 may be positioned on the upper surface of the base insulation layer 101. The protruded region 103 may be positioned between the source/drain patterns 150 and the upper surface of the base insulation layer 101. Between the source/drain patterns 150, the channel structure CH and the gate structure GS may be positioned. The plurality of source/drain patterns 150 and the plurality of channel structures CH may be alternately arranged along the first direction D1 along which the protruded region 103 extends.

In the embodiment, the source/drain patterns 150 may extend into the protruded region 103 along the third direction D3. The protruded region 103 may be positioned between the plurality of source/drain patterns 150. Referring to FIG. 2, the source/drain patterns 150 may extend further below the lower surface of the gate structure GS. The lower surface of the source/drain pattern 150 may be lower than a level lower than the lower surface of the gate structure GS. Specifically, the lower surface of the source/drain pattern 150 may be positioned at a level lower than the lower surface of the sub-gate electrode 120S positioned at the lowest among the plurality of sub-gate electrodes 120S positioned spaced apart from each other in the third direction D3 on the protruded region 103. In the embodiment, the distance d1 between the lower surface of the gate structure GS and the lower surface of the source/drain pattern 150 may be greater than or equal to about 20 nm and less than or equal to about 100 nm.

Referring to FIG. 2 to FIG. 4, the lower surface of the source/drain pattern 150 may be positioned at a higher level than the upper surface of the base insulation layer 101. In other words, the source/drain pattern 150 may extend to a level higher than the upper surface of the base insulation layer 101.

However, it is not limited thereto, the source/drain pattern 150 may extend through the protruded region 103 into the interior of the base insulation layer 101. In this case, the lower surface of the field insulation layer 105 may be positioned at a lower level than the upper surface of the base insulation layer 101.

The lower surface of the source/drain pattern 150 may be positioned at a level lower than the upper surface of the field insulation layer 105. Referring to FIG. 3 and FIG. 4, the source/drain pattern 150 may include a region overlapping the field insulation layer 105 in the second direction D2. Among the entire region of the source/drain pattern 150, the region positioned inside the recess region RC may overlap the field insulation layer 105 in the second direction D2. In the region where the source/drain pattern 150 and the field insulation layer 105 overlap, the protruded region 103 may be positioned between the source/drain pattern 150 and the field insulation layer 105. In the embodiment, the lower surface of the source/drain pattern 150 may be positioned closer to the lower wire structure 420 compared to an upper surface of a first contact region 195a, which will be described later.

In an embodiment, a ratio (d1/d2) of a first distance d1 to a second distance d2 between the upper surface of the channel pattern 110a positioned at the uppermost among the channel patterns 110a, 110b, 110c, and 110d and the upper surface of the protruded region 103 may be, for example, greater than or equal to about 0.5 and less than or equal to about 1.0. The ratio (d1/d2) of the first distance d1 to the second distance d2 may be, for example, greater than or equal to about 0.6 and less than or equal to about 0.9.

In the embodiment, the ratio (d1 /(d1+d2)) of the first distance d1 to the distance (d1+d2) between the upper and lower surfaces of the source/drain pattern 152 may be, for example, greater than or equal to about 0.2 and less than or equal to about 0.6. The ratio (d1 /(d1+d2)) of the first distance d1 to the distance (d1+d2) between the upper and lower surfaces of the source/drain pattern 152 can be, for example, greater than or equal to about 0.3 and less than or equal to about 0.5.

At least some regions of each of the source/drain patterns 150 may be surrounded by the protruded region 103. Specifically, referring to FIG. 2 to FIG. 4, the entire region of the side and lower surfaces of the source/drain pattern 150 positioned within the recess region RC may be surrounded by the protruded region 103. In the embodiment, the side and bottom surfaces of the source/drain pattern 150 positioned within the recess region RC may be in contact with the inner side and bottom surfaces of the protruded region 103, respectively.

The source/drain patterns 150 may also be arranged in the second direction D2. Referring to FIG. 1, FIG. 3 and FIG. 4, the plurality of protruded regions 103 may be arranged spaced apart along the second direction D2 over the base insulation layer 101, and the source/drain patterns 150 may be positioned over each of the protruded regions 103. The source/drain patterns 150 may be positioned to overlap each of the protruded regions 103 in the third direction D3.

The source/drain pattern 150 may be positioned on both sides of the channel structure CH, or the sub-gate structure S_GS. Specifically, two source/drain patterns 150 positioned on one protruded region 103 may be arranged spaced apart in a direction (e.g., the first direction D1) intersecting the direction in which the gate structure GS extends, with the channel structure CH and/or the sub-gate structure S_GS interposed therebetween. The source/drain pattern 150 may be in directly contact with the channel structure CH or the sub-gate structure S_GS. The source/drain pattern 150 may be in directly contact with the sub-gate insulation layer 130S of the sub-gate structure S_GS. Among the plurality of sub-gate electrodes 120S positioned spaced apart in the third direction D3, the side and lower surfaces of the source/drain pattern 150 positioned at a lower level than the lower surface of the sub-gate electrode 120S positioned at the lowest may be in directly contact with the protruded region 103.

Although not shown, an inner spacer may be additionally placed between the source/drain pattern 150 and the sub-gate insulation layer 130S. The inner spacer may include at least one of silicon nitride (SiNX), silicon oxynitride (SiON), silicon oxide SiO2, silicon carbonate nitride (SiOCN), silicon boron nitride (SiBN), silicon boron oxynitride (SiOBN), silicon oxycarbide (SiOC), and a combination thereof.

The source/drain pattern 150 may be composed of an epitaxial layer formed by a selective epitaxial growth (SEG). The source/drain patterns 150 may be formed by removing at least a partial region of the semiconductor pattern stacked on the base insulation layer 101 and then using a selective epitaxial growth method on the corresponding region. When the semiconductor pattern stacked on the base insulation layer 101 is removed, a part of the lower pattern (BP, referring to FIG. 10) positioned below the semiconductor patterns may be removed together, so that the recess region RC illustrated in FIG. 2 to FIG. 4 may be formed. Accordingly, the source/drain pattern 150 may also be formed inside the recess region RC by the selective epitaxial growth method.

The source/drain patterns 150 may each include liner layers 151a and 152a and filling layers 151b and 152b. The liner layers 151a and 152a may be positioned outside of the filling layers 151b and 152b. The sides and lower surfaces of the filling layers 151b and 152b may be surrounded by the liner layers 151a and 152a. The liner layers 151a and 152a may be in contact with the sub-gate structure S_GS and the channel structure CH. The filling layers 151b and 152b may be positioned over the liner layers 151a and 152a. The filling layers 151b and 152b and the liner layers 151a and 152a may have the upper surfaces of substantially the same height. However, it is not limited thereto, unlike that illustrated in FIG. 2, the filling layers 151b and 152b and the liner layers 151a and 152a may have the upper surfaces of different heights in some regions.

In the embodiment, the liner layers 151a and 152a may be conformally positioned along the interface with the gate structure GS and the channel structure CH, and the interface with the protruded region 103. The filling layers 151b and 152b may be positioned on the inner surface of the liner layers 151a and 152a.

In detail, referring to FIG. 2 to FIG. 4, in the region where the source/drain pattern 150 overlaps the channel structure CH and the gate structure GS in the first direction D1, the liner layers 151a and 152a may be positioned between the channel structure CH and the gate structure GS, and the filling layers 151b and 152b. In the region where the source/drain pattern 150 overlaps the channel structure CH and the gate structure GS in the first direction D1, the liner layers 151a and 152a may extend along the side surfaces of the filling layers 151b and 152b.

In the region where the source/drain pattern 150 overlaps the protruded region 103 in the first direction D1 or the second direction D2, the liner layers 151a and 152a may be positioned between the protruded region 103 and the filling layers 151b and 152b. In the region where the source/drain pattern 150 overlaps the protruded region 103 in the first direction D1 or the second direction D2, the liner layers 151a and 152a may extend along the side and lower surfaces of the filling layers 151b and 152b. Referring to FIG. 2 to FIG. 4, the liner layers 151a and 152a may be conformally positioned along the entire region of the lateral and inferior surfaces of the recess region RC. In the region where the filling layers 151b and 152b are positioned at a level lower than the lower surface of the gate structure GS, the entire side region may be surrounded by the liner layers 151a and 152a. In the region positioned at a level lower than the lower surface of the gate structure GS, the liner layers 151a and 152a may be positioned between the field insulation layer 105 and the filling layers 151b and 152b.

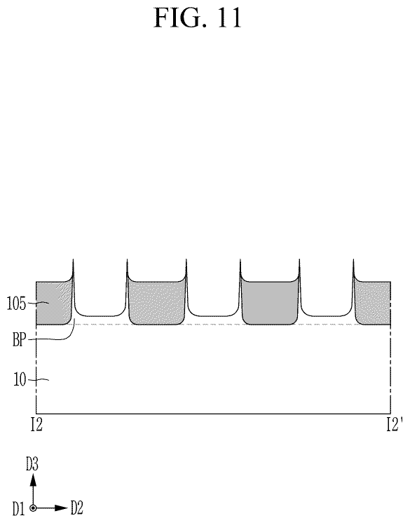

The liner layers 151a and 152a may be positioned on the sides of the filling layers 151b and 152b. In the embodiment, the liner layers 151a and 152a may be positioned over only a part of the entire lateral region of the filling layers 151b and 152b. Referring to FIG. 2, the liner layers 151a and 152a may be positioned over the entire region of two opposing side surfaces 150b_S1 and 150b_S2 of the filling layers 151b and 152b along the first direction D1. Referring to FIG. 3 and FIG. 4, the liner layers 151a and 152a may be positioned only on a part of two opposite side surfaces 150b_S3 and 150b_S4 of the filling layers 151b and 152b along the second direction D2. In detail, referring to FIG. 3 and FIG. 4, on the cross-section formed of the second direction D2 and the third direction D3, the liner layers 151a and 152a may be positioned on the side surfaces of the filling layers 151b and 152b that overlap the protruded region 103 in the first direction D1, and may not be positioned on the side surfaces of the filling layers 151b and 152b that do not overlap the protruded region 103 in the first direction D1. This may be due to the process characteristic that the liner layers 151a and 152a are formed through the selective epitaxial growth process using the plurality of channel patterns 110a, 110b, 110c, and 110d and the lower pattern (BP, referring to FIG. 10 and FIG. 11) as a seed.

Referring to FIG. 2 to FIG. 4, the side surfaces of the liner layers 151a and 152a may be in contact with the protruded region 103, the channel patterns 110a, 110b, 110c, and 110d, and the sub-gate electrodes 120S, and may not be in contact with a first interlayer insulation layer 171 described below.

Referring to FIG. 3, the region positioned at the lowest level among the entire region of the lower surface of the filling layer 152b (the region closest to the upper surface of the lower wire structure 420) may be positioned at a lower level than the region positioned at the lowest level among the entire region of the upper surface of the field insulation layer 105 (the region closest to the upper surface of the lower wire structure 420). Alternatively, the region positioned at the lowest level among the entire region of the liner layer 152a (the region closest to the upper surface of the lower wire structure 420) may be positioned at a lower level than the region positioned at the lowest level among the entire region of the upper surface of the field insulation layer 105 (the region closest to the upper surface of the lower wire structure 420).

The source/drain pattern 150 may include a semiconductor material. The source/drain pattern 150 may include, for example, silicon (Si) or germanium (Ge). Additionally, the source/drain pattern 150 may include a binary compound or a ternary compound including at least two or more of, for example, carbon (C), silicon (Si), germanium (Ge), and tin (Sn). For example, the source/drain pattern 150 may include silicon (Si), silicon-germanium (SiGe), germanium (Ge), silicon carbide (SiC), etc., but it is not limited thereto.

The liner layers 151a and 152a and the filling layers 151b and 152b may include different semiconductor materials. For example, the liner layers 151a and 152a may include silicon (Si), and the filling layers 151b and 152b may include silicon germanium (SiGe). As another example, the liner layers 151a and 152a and the filling layers 151b and 152b may include the same material. At this time, the concentrations of materials included in the liner layers 151a and 152a and the filling layers 151b and 152b may be different. For example, if the liner layers 151a and 152a and the filling layers 151b and 152b include silicon germanium (SiGe), the germanium (Ge) concentration in the filling layers 151b and 152b may be greater than the germanium (Ge) concentration in the liner layers 151a and 152a, but is not limited thereto. As another example, the filling layers 151b and 152b may include the same material as the liner layers 151a and 152a, and the filling layers 151b and 152b and the liner layers 151a and 152a may have the same concentration of a constituent material.

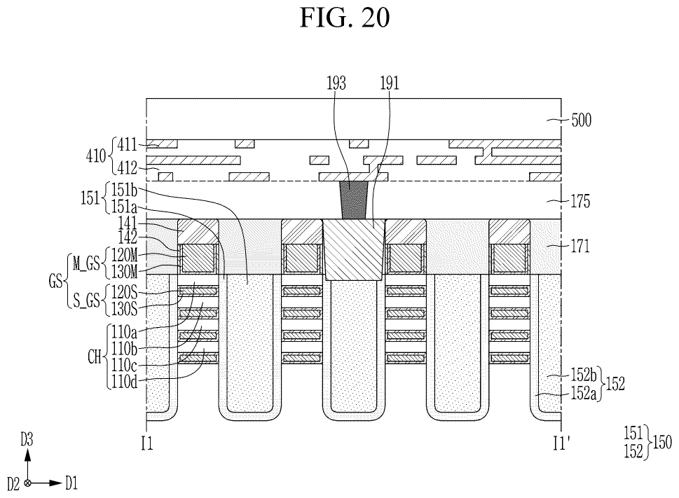

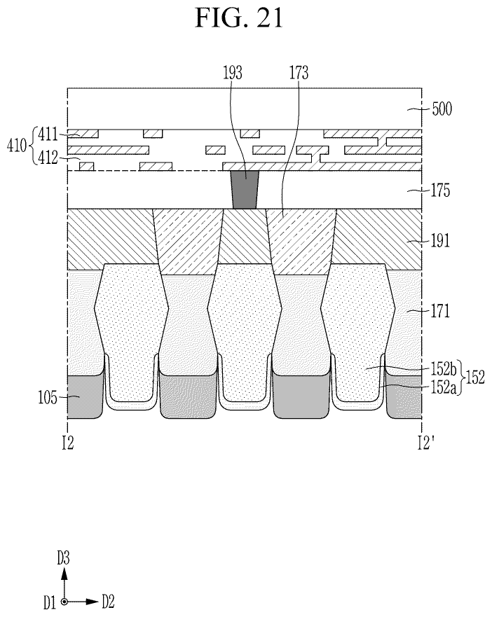

In an embodiment, the liner layers 151a and 152a may include a material having an etch selectivity with respect to the substrate 10 (referring to FIG. 20 and FIG. 21). In this case, in the process of etching the first substrate 10 described later, the source/drain pattern 150 may be prevented from being damaged by the etching material. For example, if the semiconductor device according to the embodiment is an NMOS (i.e., doped with an N-type impurity) and the first substrate 10 includes silicon (Si), the liner layers 151a and 152a may include or may be formed of silicon germanium (SiGe) doped with carbon (C). In this case, the liner layers 151a and 152a may have an etch selectivity with respect to the first substrate 10, and thus, in the process of removing the first substrate 10, the source/drain pattern 150 may be protected without the damage by the etching material.

For example, if the semiconductor device according to the embodiment is a PMOS (i.e., doped with a P-type impurity) and the first substrate 10 includes silicon (Si), the liner layers 151a and 152a may include silicon germanium (SiGe) doped with boron (B). In this case, the liner layers 151a and 152a may have an etch selectivity with respect to the first substrate 10, and thus, in the process of removing the first substrate 10, the source/drain pattern 150 may be protected without the damage by the etching material.

In an embodiment, the liner layers 151a and 152a may include silicon germanium (SiGe) doped with carbon (C) or boron (B) at a concentration below a predetermined level. The silicon germanium (SiGe) included in the liner layers 151a and 152a may have a carbon (C) or boron (B) doping concentration of, for example, less than 0.1 at % and greater than 0 at %.

In the case of the semiconductor device according to the embodiment, in the process of etching the first substrate 10, the first substrate 10 can be completely removed without the source/drain pattern 150 being damaged by the etching material. After this, the region where the first substrate 10 was positioned may be filled with the base insulation layer 101. Since the first substrate 10 is completely replaced by the base insulation layer 101, a leakage current that may flow between the adjacent source/drain patterns 150 may be reduced, thereby improving the reliability of the semiconductor device.

The semiconductor device according to the embodiment may further include a lower wire structure 420 positioned above the lower surface of the base insulation layer 101. The upper surface of the lower wire structure 420 may have some regions in contact with the lower surface of the lower contact electrode 195. The lower wire structure 420 may include lower conductive patterns 421 and a lower wire insulation layer 422. The lower conductive patterns 421 may include lower wires spaced apart in the third direction D3 and lower wire vias connecting two the lower wires. The lower conductive patterns 421 may be positioned between the lower wire insulation layers 422. The lower wire insulation layer 422 may surround the lower conductive patterns 421. For example, the lower wire insulation layer 422 may cover the lower conductive patterns 421, and the lower conductive patterns 421 may be positioned within the lower wire insulation layer 422.

The lower conductive patterns 421 may include metal (e.g., copper). The lower wire insulation layer 422 may include, for example, at least one of silicon oxide SiO2, silicon nitride (SiNX), silicon oxynitride (SiON), or low dielectric layers.

The semiconductor device according to the embodiment may include a lower contact electrode 195 connecting the lower wire structure 420 and the source/drain pattern 150. The lower contact electrode 195 may connect at least one source/drain pattern 151 among the source/drain patterns 150 to the lower wire structure 420. Referring to FIG. 2 and FIG. 4, the lower contact electrode 195 may be connected to the first source/drain pattern 151 by penetrating the base insulation layer 101 in the third direction D3. Referring to FIG. 1, in the top view, the lower contact electrode 195 is depicted as having a quadrangle shape, but is not limited thereto, and the lower contact electrode 195 may have a circle, or any other polygonal shape other than a quadrangle.

In an embodiment, the lower contact electrode 195 may include a first contact region 195a positioned on the upper surface of the lower wire structure 420, and a second contact region 195b positioned on the upper surface of the first contact region 195a. The first contact region 195a may extend from the upper surface of the lower wire structure 420 into the base insulation layer 101 along the third direction D3. The first contact region 195a may penetrate the upper surface of the base insulation layer 101.

The first contact region 195a may have an inclined side surface in which the width of the upper region is narrower than the width of the lower region depending on an aspect ratio. The width of the first contact region 195a along the first direction D1 may be wider than the width of the source/drain pattern 150 along the first direction D1. Referring to FIG. 2, the width of the first contact region 195a along the first direction D1 may be wider than the width of the source/drain pattern 150 along the first direction D1.

Referring to FIG. 4, on the same plane as the interface of the upper surface of the base insulation layer 101 and the lower surface of the field insulation layer 105, the width of the first contact region 195a along the second direction D2 may be wider than the width of the protruded region 103 along the second direction D2. In the embodiment, the first contact region 195a may extend further into the protruded region 103 along the third direction D3, penetrating the base insulation layer 101. In the region where the first contact region 195a overlaps the field insulation layer 105 in the second direction D2, the side of the first contact region 195a may be positioned along the side of the field insulation layer 105.

In the embodiment, the upper surface of the first contact region 195a may be positioned at a higher level than the lower surface of the source/drain pattern 150. For example, referring to FIG. 2, the upper surface of the first contact region 195a may be positioned between the upper surface and the lower surface of the second source/drain pattern 152, which is positioned apart from the first source/drain pattern 151 in the first direction D1. Specifically, the upper surface of the first contact region 195a may be positioned at a higher level than the lower surface of the first source/drain pattern 151, which overlaps the lower contact electrode 195 in the third direction D3, and the second source/drain pattern 152, which is adjacent in the first direction D1, among the source/drain patterns 150.

The second contact region 195b may extend from the upper surface of the first contact region 195a along the third direction D3 into the first source/drain pattern 151. Referring to FIG. 2 and FIG. 4, the second contact region 195b may have an inclined side surface in which the upper region is narrower than the lower region depending on the aspect ratio. In the embodiment, the width of the second contact region 195b along the first direction D1 may be equal to or narrower than the width of the source/drain pattern 150 along the first direction D1. In the embodiment, the width of the second contact region 195b along the second direction D2 may be equal to or narrower than the width of the source/drain pattern 150 along the second direction D2.

Referring to FIG. 2, at the boundary between the first contact region 195a and the second contact region 195b, the second contact region 195b may have a narrower width along the first direction D1 compared to the first contact region 195a. Accordingly, the gate contact portion 190 may include a bend portion positioned at the boundary between the first contact region 195a and the second contact region 195b. In the embodiment, the lower surface of the source/drain pattern 150 may be positioned at a level lower than the bend portion positioned at the boundary between the first contact region 195a and the second contact region 195b.

Specifically, the region positioned at the lowest level among the entire region of the lower surface of the liner layer 152a (the region closest to the upper surface of the lower wire structure 420) may be positioned at a lower level than the bend portion positioned at the boundary between the first contact region 195a and the second contact region 195b. Specifically, the region positioned at the lowest level among the entire region of the lower surface of the filling layer 152b (the region closest to the upper surface of the lower wire structure 420) may be positioned at a lower level than the bend portion positioned at the boundary between the first contact region 195a and the second contact region 195b.

In the embodiment, the upper surface of the second contact region 195b may be positioned between the lower surface of the gate structure GS and the upper surface of the source/drain pattern 150. The upper surface of the second contact region 195b may be positioned at a higher level than the level of the upper surface of the protruded region 103. The second contact region 195b may overlap at least one of the channel patterns 110a, 110b, 110c, and 110d in the first direction D1. Referring to FIG. 2, the second contact region 195b is depicted as overlapping in the first direction D1 only the channel pattern 110d positioned at the lowest position among the plurality of channel patterns 110a, 110b, 110c, and 110d positioned spaced apart in the third direction D3, but is not limited thereto. For example, the second contact region 195b may overlap the channel pattern 110d positioned at the bottom and the channel pattern 110c positioned thereon in the first direction D1.

The lower contact electrode 195 may include at least one of a metal, a metal alloy, a conductive metal nitride, a conductive metal carbide, a conductive metal oxide, a conductive metal carbon nitride, and a two-dimensional material. The metal may include at least one of titanium (Ti), tantalum (Ta), tungsten (W), nickel (Ni), cobalt (Co), and platinum (Pt). The conductive metal nitride may include at least one of titanium nitride (TiN), tantalum nitride (TaN), tungsten nitride (WN), nickel nitride (NiN), cobalt nitride (CoN), and platinum nitride (PtN).

The semiconductor device according to the embodiment may further include a barrier pattern 197 positioned along the side and upper surfaces of the lower contact electrode 195. The barrier pattern 197 may cover the side and upper surfaces of the lower contact electrode 195. The barrier pattern 197 may include a metal, a metal alloy, or a conductive metal nitride. The metal may include at least one of titanium (Ti), tantalum (Ta), tungsten (W), nickel (Ni), cobalt (Co), and platinum (Pt). The conductive metal nitride may include at least one of titanium nitride (TiN), tantalum nitride (TaN), tungsten nitride (WN), nickel nitride (NiN), cobalt nitride (CoN), and platinum nitride (PtN). Unlike what is illustrated in FIG. 1 to FIG. 5, the semiconductor device according to the embodiment may not include the barrier pattern 197.

The semiconductor device according to the embodiment may further include a silicide layer 199 positioned between the second contact region 195b and the first source/drain pattern 151. The silicide layer 199 may extend between the first source/drain pattern 151 and the second contact region 195b, and along at least a portion of the side and top surface of the second contact region 195b.

The semiconductor device according to the embodiment may further include a first interlayer insulation layer 171. The first interlayer insulation layer 171 may be positioned on the side surface of the gate spacer 142, the side surface of the capping layer 141, and the upper surface of the source/drain patterns 150. Referring to FIG. 3 and FIG. 4, the first interlayer insulation layer 171 may cover at least a portion of the side surfaces of the source/drain pattern 150. The first interlayer insulation layer 171 may cover the field insulation layer 105. The first interlayer insulation layer 171 may not cover the upper surface of the capping layer 141.

Referring to FIG. 3, the region positioned at the lowest level among the entire region of the lower surface of the filling layer 152b (the region closest to the upper surface of the lower wire structure 420) may be positioned at a lower level than the region positioned at the lowest level among the entire region of the lower surface of the first interlayer insulation layer 171 (the region closest to the upper surface of the lower wire structure 420). Alternatively, the region positioned at the lowest level among the entire regions of the liner layer 152a (the region closest to the upper surface of the lower wire structure 420) may be positioned at a lower level than the region positioned at the lowest level among the entire region of the lower surface of the first interlayer insulation layer 171 (the region closest to the upper surface of the lower wire structure 420).

The first interlayer insulation layer 171 may include, for example, at least one of silicon oxide SiO2, silicon nitride (SiN), silicon oxynitride (SiON), and a low dielectric constant material. The low dielectric constant material, for example, may include Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethyleyCloTetraSiloxane (OMCTS), HexaMethylDiSiloxane (HMDS), TriMethylSilyl Borate (TMSB), DiAcetoxyDitertiaryButoSiloxane (DADBS), TriMethylSilil Phosphate (TMSP), PolyTetraFluoroEthylene (PTFE), TOSZ(Tonen SilaZen), FSG (Fluoride silicate glass), polyimide nanofoams such as polypropylene oxide, CDO (Carbon Doped silicon Oxide), OSG (Organo silicate glass), SiLK, Amorphous Fluorinated Carbon, silica aerogels, silica xerogels, mesoporous silica or combination thereof, but it is not limited thereto.

The semiconductor device according to the embodiment may include an upper contact electrode 191. The upper contact electrode 191 may be positioned on the source/drain pattern 150. The upper contact electrode 191 may be connected to at least one second source/drain pattern 152, which is not connected to the lower contact electrode 195 among the plurality of source/drain patterns 150, and can provide an electrical signal or a power voltage provided from an external source to the second source/drain pattern 152.

The semiconductor device according to the embodiment may include a plurality of upper contact electrodes 191. The plurality of upper contact electrodes 191 may be arranged along the second direction D2. At this time, a separation pattern 173 may be positioned between the upper contact electrodes 191 arranged spaced apart along the second direction D2. For example, referring to FIG. 1 and FIG. 3, the plurality of upper contact electrodes 191 are arranged spaced apart from each other along the second direction D2, and the separation pattern 173 may be positioned between the upper contact electrodes 191, respectively.

Referring to FIG. 1 to FIG. 3, the upper surface of the upper contact electrode 191 may be positioned on the same plane as the surface including the upper surface of the first interlayer insulation layer 171 and the upper surface of the capping layer 141.

Referring to FIG. 1 and FIG. 2, the upper contact electrode 191 may penetrate a portion of the first interlayer insulation layer 171 in the third direction D3 in the region where the first interlayer insulation layer 171 overlaps the second source/drain pattern 152 in the third direction D3. At this time, the lower surface of the upper contact electrode 191 may come into contact with the second source/drain pattern 152. Referring to FIG. 2, the upper contact electrode 191 may be recessed from the upper surface of the second source/drain pattern 152 to the upper surface direction of the first substrate 10 by a predetermined depth. However, it is not limited thereto, and the upper contact electrode 191 may have a lower surface that is in contact with the upper surface of the second source/drain pattern 152 pattern. Referring to FIG. 3, the upper contact electrode 191 may cover at least some regions of the upper surface and side surfaces of the second source/drain pattern 152.

The upper contact electrode 191 may include a conductive material. For example, the upper contact electrode 191 may include at least one of a metal, a metal alloy, a conductive metal nitride, a conductive metal carbide, a conductive metal oxide, a conductive metal nitride, and a two-dimensional 2D material. The metal may include at least one of titanium (Ti), tantalum (Ta), tungsten (W), nickel (Ni), cobalt (Co), and platinum (Pt). The conductive metal nitride may include at least one of titanium nitride (TiN), tantalum nitride (TaN), tungsten nitride (WN), nickel nitride (NiN), cobalt nitride (CoN), and platinum nitride (PtN).

The semiconductor device according to an embodiment may further include a separation pattern 173 positioned between the plurality of upper contact electrodes 191. The separation pattern 173 may also be positioned between the source/drain patterns 150. The separation pattern 173 may electrically isolate the adjacent upper contact electrodes 191 from each other. For example, referring to FIG. 1 and FIG. 3, the separation pattern 173 may be positioned between the plurality of upper contact electrodes 191 arranged spaced apart from each other in the second direction D2. The separation pattern 173 may include an insulating material, in which case two upper contact electrodes 191 positioned on either side of the separation pattern 173 may be electrically isolated from each other. In an embodiment, the separation pattern 173 may have a side in contact with upper contact electrodes 191 positioned on both sides.

The separation pattern 173 may include an insulating material. For example, the separation pattern 173 may include silicon nitride (SiNX), silicon oxide (SiOx), and/or silicon carbon nitride (SiCxNy). However, this is not limited thereto, and the separation pattern 173 may include various insulating materials to electrically isolate the upper contact electrodes 191 from each other.

In an embodiment, the semiconductor device may further include a second interlayer insulation layer 175, an upper wire structure 410, and an upper contact via 193 positioned over the first interlayer insulation layer 171.

The second interlayer insulation layer 175 may cover the first interlayer insulation layer 171, a portion of the upper surface of the upper contact electrode 191, the upper surface of the capping layer 141, and the upper surface of the separation pattern 173. The second interlayer insulation layer 175 may include an insulating material. The second interlayer insulation layer 175 may include an insulating material that is the same as or different from the first interlayer insulation layer 171. In an embodiment, when the second interlayer insulation layer 175 includes an insulating material different from the first interlayer insulation layer 171, the boundary between the first interlayer insulation layer 171 and the second interlayer insulation layer 175 may not be visible.

The upper wire structure 410 may be positioned above the second interlayer insulation layer 175. The lower surface of the upper wire structure 410 may be in contact with some regions of the upper surface of the upper contact via 193 described below. The upper wire structure 410 may include upper conductive patterns 411 and an upper wire insulation layer 412. The upper conductive patterns 411 may include upper wires spaced apart in the third direction D3 and upper wire vias connecting two upper wires. The upper conductive patterns 411 may be positioned between the upper wire insulation layers 412. The upper wire insulation layer 412 may surround the upper conductive patterns 411. That is, the upper wire insulation layer 412 may cover the upper conductive patterns 411, and the upper conductive patterns 411 may be positioned within the upper wire insulation layer 412.

The upper conductive patterns 411 may include a metal (e.g., copper). The upper wire insulation layer 412 may include, for example, at least one of silicon oxide (SiO₂), silicon nitride (SiNX), silicon oxynitride (SiON), or low dielectric layers.

The upper contact via 193 may be positioned between the upper wire structure 410 and the upper contact electrode 191. The upper contact via 193 may penetrate some region of the second interlayer insulation layer 175. The lower surface of the upper contact via 193 may be in contact with the upper surface of the upper contact electrode 191, and the upper surface may be in contact with some of the upper conductive patterns 411 of the upper wire structure 410. The upper contact via 193 may be connected to the second source/drain pattern 152 via the upper contact electrode 191.

The upper contact via 193 may include a conductive material. For example, the upper contact via 193 may include at least one of a metal, a metal alloy, a conductive metal nitride, a metal silicide, a doped semiconductor material, a conductive metal oxide, and a conductive metal oxynitride.

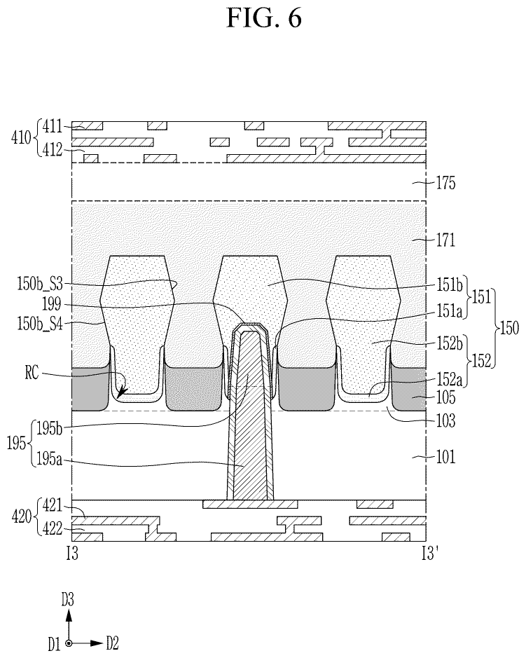

FIG. 6 is a cross-sectional view showing a semiconductor device according to the embodiment. The semiconductor device illustrated in FIG. 6 is substantially the same as the previous embodiments, so the following explanation focuses on the differences from the previous embodiments. Specifically, the semiconductor device illustrated in FIG. 6 may have the width of the lower contact electrode 195 along the second direction D2 that is somewhat different compared to the preceding embodiments.

Referring to FIG. 6, in the embodiment, the width of the lower contact electrode 195 along the second direction D2 may be narrower compared to the width of the source/drain pattern 150 along the second direction D2.

Specifically, referring to FIG. 6, on the same plane as the interface between the upper surface of the base insulation layer 101 and the lower surface of the field insulation layer 105, the width of the first contact region 195a along the second direction D2 may be narrower than the width of the protruded region 103 along the second direction D2. In the embodiment, the first contact region 195a may extend further into the protruded region 103 and the first source/drain pattern 151 along the third direction D3, penetrating the base insulation layer 101. In the embodiment, the silicide layer 199 may be positioned on the side of the region that overlaps the first source/drain pattern 151 in the second direction D2 among the first contact region 195a.

The second contact region 195b may extend from the upper surface of the first contact region 195a along the third direction D3 into the first source/drain pattern 151. The second contact region 195b may have a sloping side surface with the upper region being narrower than the lower region, depending on the aspect ratio. In the embodiment, the width of the second contact region 195b along the second direction D2 may be narrower than the width of the source/drain pattern 150 along the second direction D2.

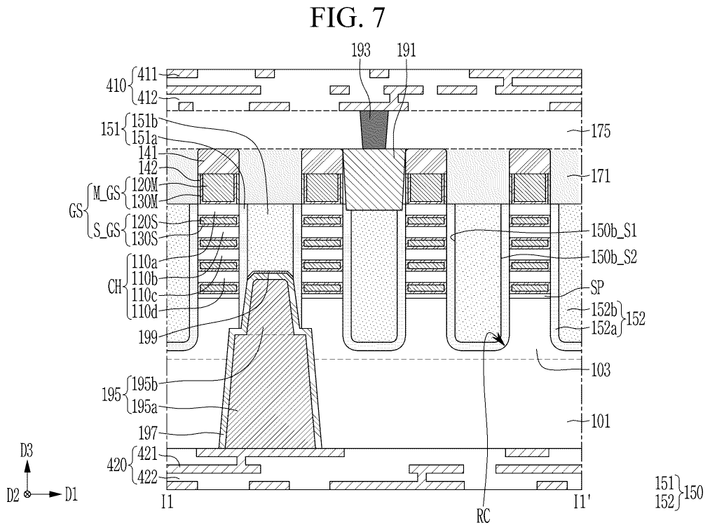

FIG. 7 is a cross-sectional view showing a semiconductor device according to embodiment. The semiconductor device illustrated in FIG. 7 is substantially the same as the previous embodiments, so the following explanation focuses on the differences from the previous embodiments. Specifically, the semiconductor device illustrated in FIG. 7 may differ from the preceding embodiments in some respects in that it further includes a semiconductor pattern (SP).

Referring to FIG. 7, in the embodiment, the semiconductor pattern SP may be positioned between the gate structure GS and the protruded region 103. The semiconductor pattern SP illustrated in FIG. 7 may be a portion where some regions of the lower pattern BP are not completely etched by the etching material and remain in the process of removing the first substrate 10 and the lower pattern BP described later (referring to FIG. 20 and FIG. 21).

The semiconductor pattern SP may be positioned between the sub-gate electrode 120S and the protruded region 103, in the region where the protruded region 103 overlaps the gate structure GS. Referring to FIG. 7, the semiconductor pattern SP has the side surface in contact with the source/drain pattern 150, and the upper surface and the lower surface in contact with the lower surface of the sub-gate electrode 120S and the upper surface of the protruded region 103, respectively. The semiconductor pattern SP may not be positioned in the region where the protruded region 103 overlaps the source/drain pattern 150 in the third direction D3.

The semiconductor pattern SP may include semiconductor materials, such as Group IV semiconductors such as Si and Ge, Group III-V compound semiconductors, and Group II-VI compound semiconductors. In an embodiment, the semiconductor pattern SP may include the same material as the channel structure CH.

FIG. 8 to FIG. 32 are process cross-sectional views for explaining a manufacturing method of a semiconductor device according to an embodiment.

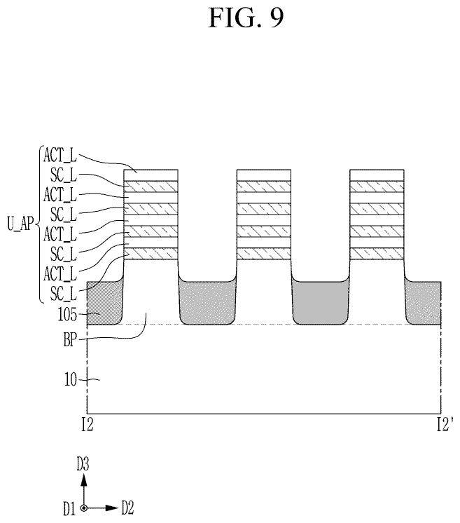

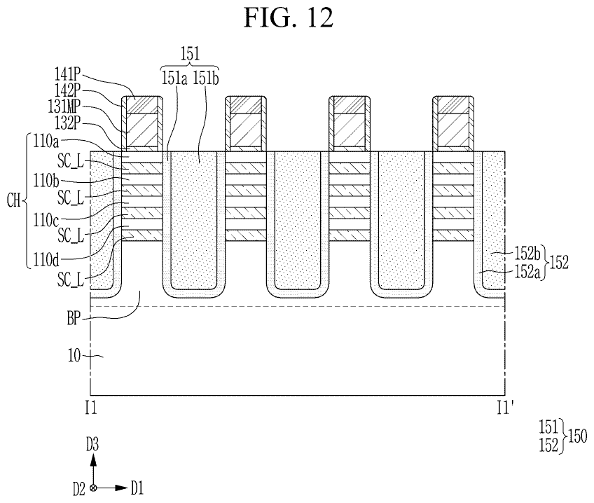

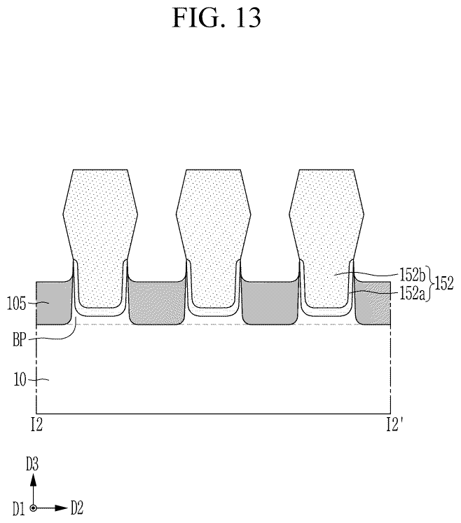

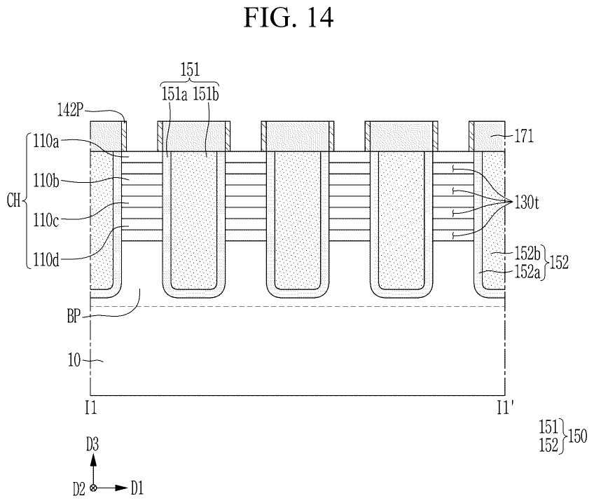

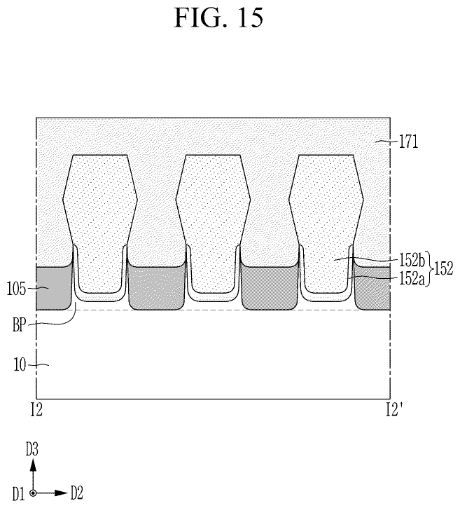

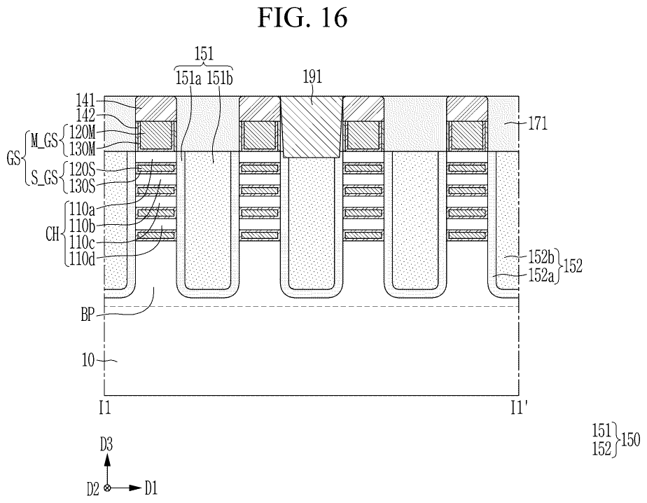

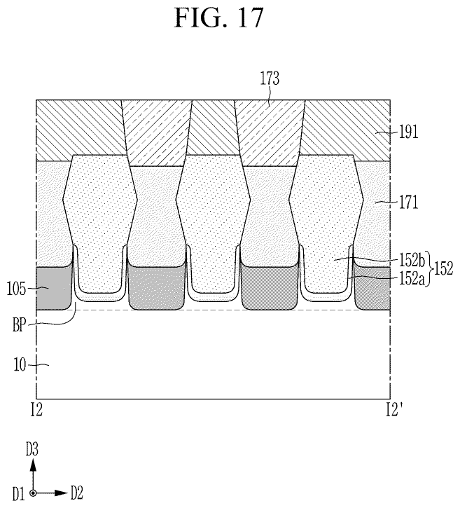

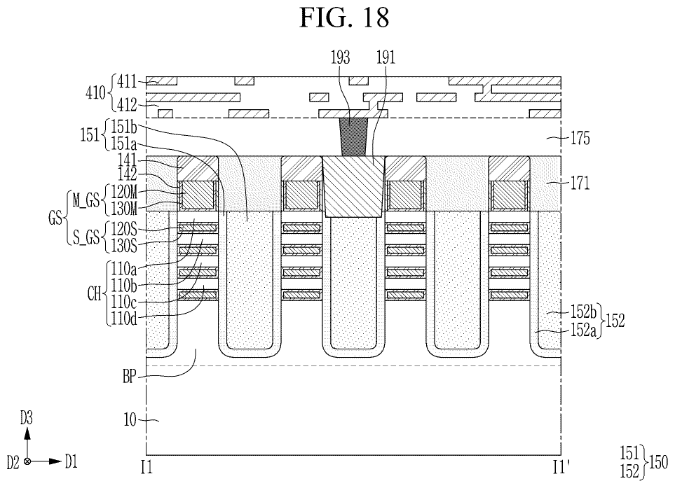

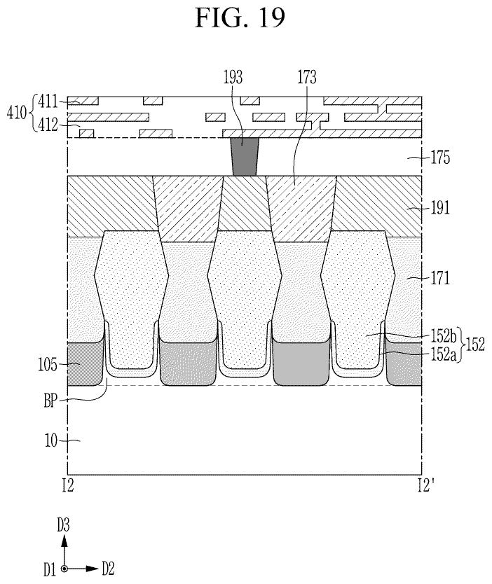

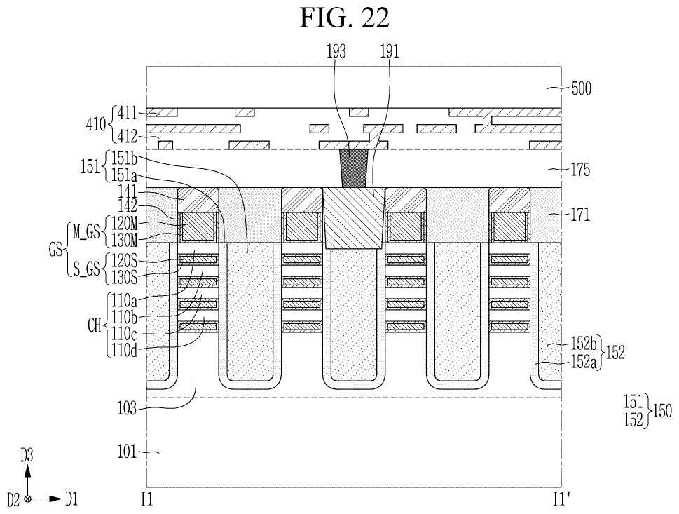

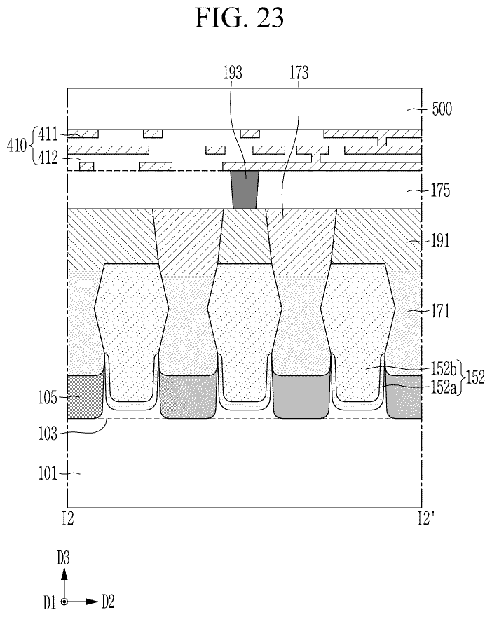

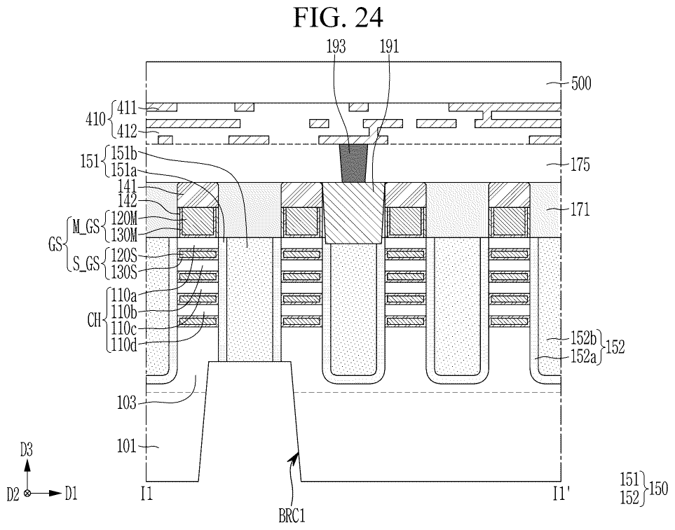

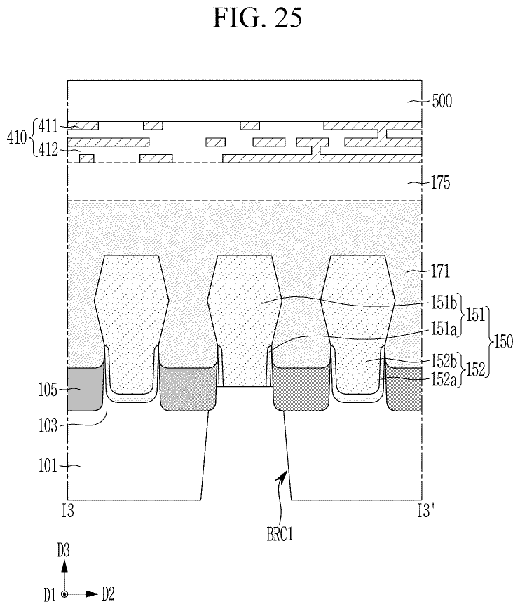

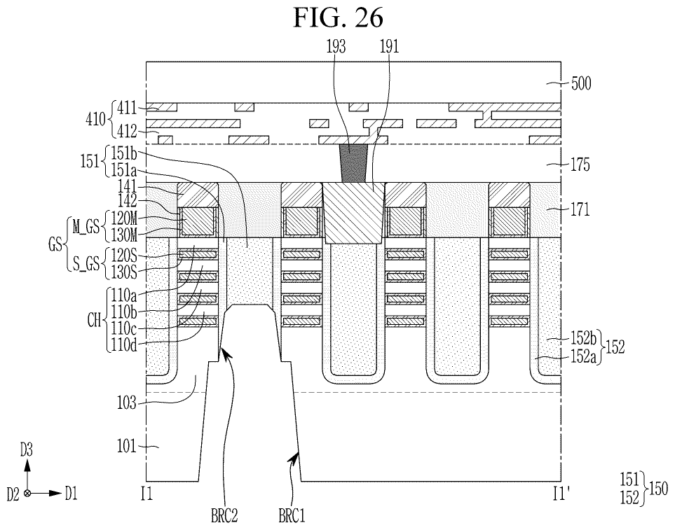

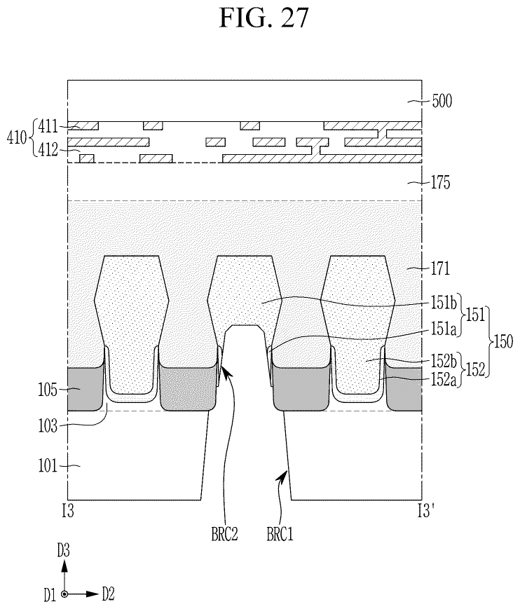

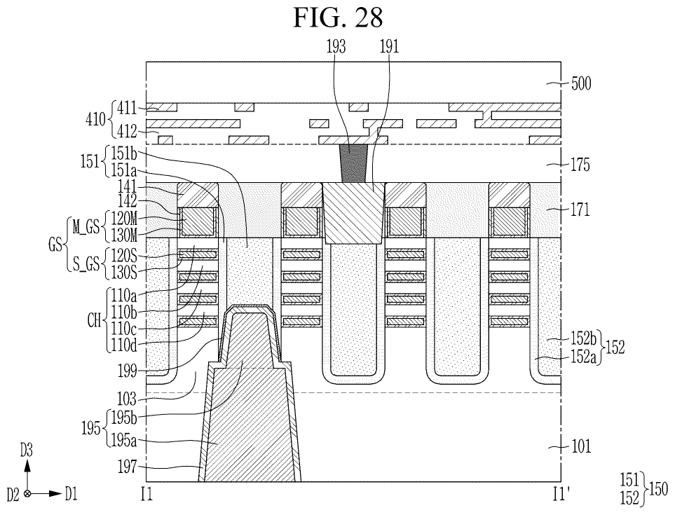

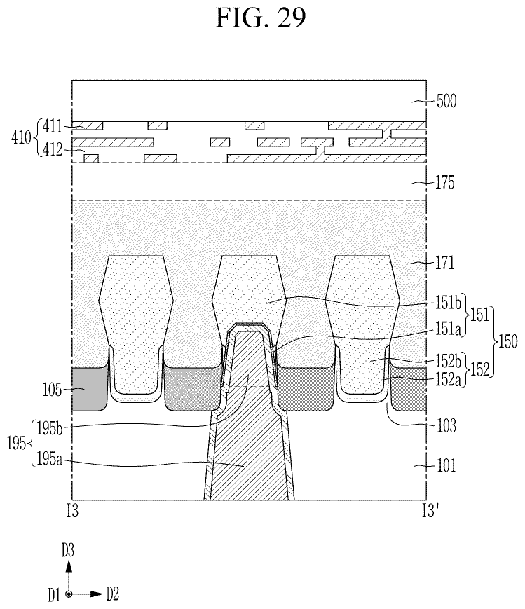

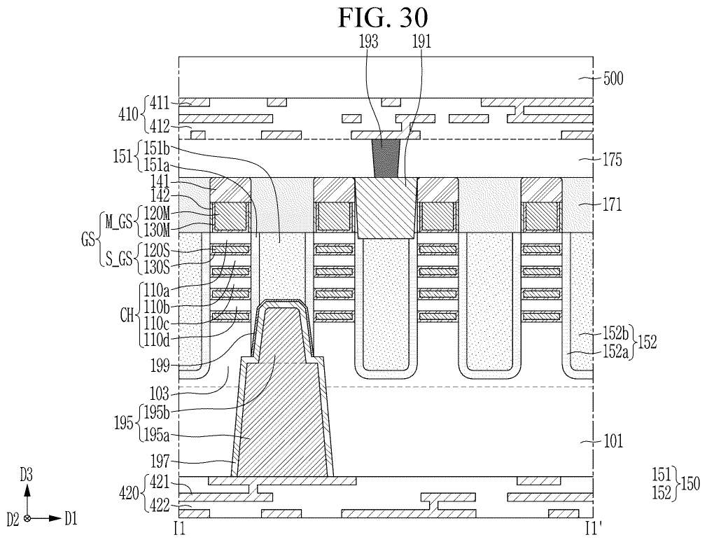

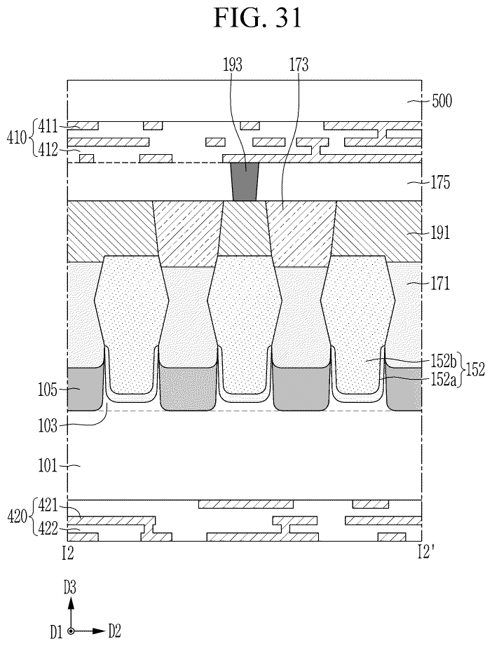

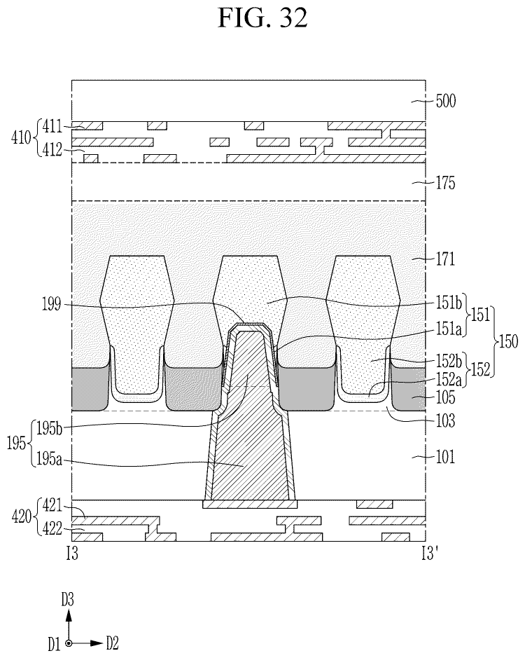

FIG. 8, FIG. 10, FIG. 12, FIG. 14, FIG. 16, FIG. 18, FIG. 20, FIG. 22, FIG. 24, FIG. 26, FIG. 28 and FIG. 30 are cross-sectional views corresponding to a region cut along the line I1-I1′ of FIG. 1 to explain the manufacturing method of the semiconductor device according to an embodiment. FIG. 9, FIG. 11, FIG. 13, FIG. 15, FIG. 17, FIG. 19, FIG. 21, FIG. 23, and FIG. 31 are cross-sectional views corresponding to a region cut along the line I2-I2′ of FIG. 1 for explaining the manufacturing method of the semiconductor device according to an embodiment. FIG. 25, FIG. 27, FIG. 29 and FIG. 32 are cross-sectional views corresponding to a region cut along the line I3-I3′ of FIG. 1 to explain the manufacturing method of the semiconductor device according to an embodiment.

As shown in FIG. 8 and FIG. 9, a lower pattern BP and an upper pattern structure U_AP may be formed on a first substrate 10.

Specifically, a sacrificial pattern SC_L and an active pattern ACT_L may be alternately stacked on the first substrate 10 using an epitaxial growth method, and then some regions thereof may be etched to form the upper pattern structure U_AP. At this time, a part of the first substrate 10 may be etched to form the lower pattern BP. Alternatively, the lower pattern BP may be formed by growing it on the first substrate 10 via the epitaxial growth method and then etching it together when the sacrificial pattern SC_L and the active pattern ACT_L are etched.

The first substrate 10 may be a silicon-on-insulator (SOI) or a bulk silicon. Alternatively, the first substrate 10 may be a silicon substrate, or may include other materials, such as silicon germanium (SiGe), silicon germanium on insulator (SGOI), indium antimony, lead tellurium compound, indium arsenic, indium phosphide, gallium arsenic or gallium antimony, but it is not limited thereto.

The lower pattern BP may include semiconductor materials such as silicon (Si) or germanium (Ge). In contrast, the lower patterns BP may include compound semiconductors. For example, the lower patterns BP may include Group IV-IV compound semiconductors or Group III-V compound semiconductors. The Group IV-IV compound semiconductor may be, for example, a binary compound or a ternary compound containing carbon (C), silicon (Si), germanium (Ge), tin (Sn), or a combination thereof. The III-V Group compound semiconductor may be, for example, a binary compound, a ternary compound, or a quaternary compound formed by combining Group III elements such as aluminum (Al), gallium (Ga), indium (In), or a combination thereof, and Group V elements such as phosphorus (P), arsenic (As), antimuonium (Sb), or a combination thereof. The sacrificial pattern SC_L may include silicon germanium (SiGe). The active pattern ACT_L may include silicon (Si).

Next, a field insulation layer 105 that covers at least a portion of the upper surface of the first substrate 10 and the side surface of the lower pattern BP may be formed. The field insulation layer 105 may be formed by first depositing an insulation layer on the first substrate 10, the lower pattern BP, and the upper pattern structure U_AP, and then etching some regions. Unlike what is shown, the field insulation layer 105 may be formed to cover a portion of the side surface of the upper pattern structure U_AP.

Next, on the upper pattern structure U_AP, a preliminary gate insulation layer 132P, a preliminary main gate electrode 131MP, and a preliminary capping layer 141P may be formed. The preliminary gate insulation layer 132P may include silicon oxide (SiO₂), for example, but is not limited to. The spare main gate electrode 131MP may include polysilicon, but is not limited thereto. The preliminary capping layer 141P may include silicon nitride (SiNX), but is not limited thereto. The preliminary gate spacer 142P may be formed on both sides of the preliminary main gate electrode 131MP.

As shown in FIG. 10 and FIG. 11, using the preliminary capping layer 141P and the preliminary gate spacer 142P as masks, at least a portion of the upper pattern structure U_AP may be etched to form a source/drain recess 150R. Specifically, a part of the upper pattern structure U_AP positioned between two preliminary main gate electrodes 131MP arranged along the first direction D1 may be etched.

As the source/drain recess 150R is formed, the channel structures CH may be formed while the active pattern ACT_L may be separated. The channel structures CH may be positioned on both sides of the source/drain recess 150R. The plurality of channel patterns 110a, 110b, 110c, and 110d and the sacrificial pattern SC_L included in the channel structure CH may be alternately stacked in the third direction D3. At this time, the lengths of each of the plurality of channel patterns 110a, 110b, 110c, and 110d may be different or the same.

According to the embodiment, a portion of the lower pattern BP may be etched during the process of forming the source/drain recess 150R. For example, as illustrated in FIG. 10 and FIG. 11, the lower pattern BP may be etched to a portion adjacent to the interface between the first substrate 10 and the lower pattern BP. Referring to FIG. 10 and FIG. 11, the bottom surface of the source/drain recess 150R may be positioned at a higher level than the interface of the first substrate 10 and the lower pattern BP. In another embodiment, the source/drain recess 150R may be formed through the lower pattern BP to a portion of the first substrate 10. In this case, the bottom surface of the source/drain recess 150R may be positioned at a level lower than the interface of the first substrate 10 and the lower pattern BP.

In the embodiment, when a portion of the lower pattern BP is etched, the field insulation layer 105 positioned on both sides of the lower pattern BP may be used as a mask. In the region overlapping the field insulation layer 105 in the second direction D2, the width of the source/drain recess 150R along the second direction D2 may become narrower as it approaches the upper surface of the first substrate 10. Accordingly, in the region overlapping the field insulation layer 105 in the second direction D2, the lower pattern BP may not be completely etched and may remain partially. Specifically, referring to FIG. 11, the lower pattern BP may remain without being completely etched between the side surface of the field insulation layer 105 and the source/drain recess 150R. In the embodiment, some regions of the lower pattern BP that remain unetched may be used as a seed for forming the source/drain pattern 150 thereafter.

As illustrated in FIG. 12 and FIG. 13, a source/drain pattern 150 may be formed within the source/drain recess (150R, referring to FIG. 10). The source/drain pattern 150 may be formed on the first substrate 10. The source/drain pattern 150 may be formed by using an epitaxial growth method.

The source/drain pattern 150 may be in contact with the channel patterns 110a, 110b, 110c, and 110d and the sacrifice pattern SC_L. The source/drain pattern 150 may include silicon (Si), germanium (Ge) or silicon germanium (SiGe). The source/drain pattern 150 may consist of multiple regions with different concentrations. For example, referring to FIG. 12 and FIG. 13, the source/drain pattern 150 may include liner layers 151a and 152a and filling layers 151b and 152b. The liner layers 151a and 152a and the filling layers 151b and 152b may be formed sequentially. The liner layers 151a and 152a and the filling layers 151b and 152b may each be formed using an epitaxial growth method.

First, the liner layers 151a and 152a may be conformally formed along the interior wall of the source/drain recess 150R. At this time, the channel patterns 110a, 110b, 110c, and 110d and the lower pattern BP positioned on the interior wall of the source/drain recess 150R may be used as seeds. Referring to FIG. 12, in the cross-sectional view formed by the first direction D1 and the third direction D3, the liner layers 151a and 152a may be formed using the channel patterns 110a, 110b, 110c, and 110d and the lower pattern BP as the seeds.

Referring to FIG. 13, in the cross-sectional view consisting of the first direction D1 and the third direction D3, the liner layers 151a and 152a may be formed using the lower pattern BP as the seed. Specifically, as described with reference to FIG. 11 and FIG. 12, after a portion of the lower pattern BP is recessed, the liner layers 151a and 152a may be formed along the interior wall of the remaining lower pattern BP. In the process of forming the source/drain recess 150R described with reference to FIG. 10 and FIG. 11, since a part of the upper pattern structure U_AP positioned between two preliminary main gate electrodes 131MP arranged along the first direction D1 is removed, on the cross-section formed by the second direction D2 and the third direction D3, the channel patterns 110a, 110b, 110c, and 110d as shown in FIG. 12 may not be positioned on the lower pattern BP. Accordingly, as illustrated in FIG. 13, in the cross-sectional view formed of the second direction D2 and the third direction D3, the liner layers 151a and 152a may be formed only on the interior wall of the lower pattern BP.

In the embodiment, the liner layers 151a and 152a may include silicon germanium (SiGe) doped with carbon (C) or boron (B). For example, if the semiconductor device according to the embodiment is an NMOS, the liner layers 151a and 152a may include silicon germanium (SiGe) doped with carbon (C). For example, if the semiconductor device according to the embodiment is PMOS, the liner layers 151a and 152a may include silicon germanium (SiGe) doped with boron (B).

Next, the filling layers 151b and 152b may be formed using the liner layers 151a and 152a as seeds. The filling layers 151b and 152b may fill the remaining regions of the source/drain recess 150R region, excluding the region where the liner layers 151a and 152a are formed. Referring to FIG. 12 and FIG. 13, the upper surfaces of the liner layers 151a and 152a and the filling layers 151b and 152b may have an upper surface positioned at substantially the same level as the upper surface of the channel pattern 110a positioned at the uppermost among the channel patterns 110a, 110b, 110c, and 110d. In the embodiment, the liner layers 151a and 152a and the filling layers 151b and 152b may include silicon germanium (SiGe). In the embodiment, the liner layers 151a and 152a and the filling layers 151b and 152b may have different germanium (Ge) concentrations. For example, the concentration of germanium (Ge) included in the liner layers 151a and 152a may be less than the concentration of germanium (Ge) included in the filling layers 151b and 152b.

As illustrated in FIG. 14 and FIG. 15, a first interlayer insulation layer 171 may be formed over the source/drain pattern 150. Next, a portion of the first interlayer insulation layer 171 and the preliminary capping layer 141P may be removed to expose the upper surface of the preliminary main gate electrode 131MP. At this time, a part of the preliminary gate spacer 142P may be removed together to form a gate spacer 142. Afterwards, the remaining preliminary gate insulation layers 132P and the preliminary main gate electrodes 131MP may be removed to expose the upper pattern structure U_AP between the gate spacers 142.

Next, the sacrifice pattern SC_L between the channel structure CH and the lower pattern BP may be removed. By the removal, a gate trench 130t may be formed.

As shown in FIG. 16 and FIG. 17, a sub-gate insulation layer 130S and a sub-gate electrode 120S may be sequentially formed within the gate trench 130t. Additionally, a main gate insulation layer 130M, a main gate electrode 120M, and a capping layer 141 may be formed sequentially. The sub-gate insulation layer 130S and the main gate insulation layer 130M may be formed simultaneously in the same process. The sub-gate electrode 120S and the main gate electrode 120M may be formed simultaneously in the same process.

Next, a portion of the first interlayer insulation layer 171 between two source/drain patterns 150 positioned apart along the second direction D2 may be etched by a photo and etching process to form a separation pattern 173. After this, a portion of the first interlayer insulation layer 171 positioned between two gate structures GS facing each other along the first direction D1 may be etched, and then an upper contact electrode 191 may be formed in the region where the first interlayer insulation layer 171 is removed.

As shown in FIG. 18 and FIG. 19, a second interlayer insulation layer 175, an upper contact via 193, and an upper wire structure 410 may be formed on the first interlayer insulation layer 171. First, the second interlayer insulation layer 175 may be formed on the first interlayer insulation layer 171, and a contact hole may be formed by etching a portion of the second interlayer insulation layer 175 that overlaps the upper contact electrode 191 in the third direction D3. After this, a conductive material may be deposited in the contact hole formed in the second interlayer insulation layer 175 to form the upper contact via 193, and the upper wire structure 410 may be formed on the second interlayer insulation layer 175.

As shown in FIG. 20 and FIG. 21, the first substrate 10 and the lower pattern BP may be etched. To etch the first substrate 10 and the lower pattern BP, the semiconductor device according to the embodiment may be attached to a second substrate 500. Specifically, after the upper surface of the upper wire structure 410 is positioned to face one surface of the second substrate 500, one surface of the second substrate 500 and the upper surface of the upper wire structure 410 may be attached to each other. At this time, the semiconductor device according to the embodiment may be rotated so that the upper surface of the upper wire structure 410 and the upper surface of the second substrate 500 face each other. Although not shown in FIG. 20 and FIG. 21, an adhesive member may be positioned between one surface of the second substrate 500 and the upper surface of the upper wire structure 410.

After this, by performing the etching process, the entire region of the first substrate 10 and the lower pattern BP may be removed. To remove the first substrate 10 and the lower pattern BP, at least one of a wet etching, a dry etching, and a chemical mechanical polishing (CMP) processes may be performed. For example, the first substrate 10 may be etched to be sufficiently thin by the chemical mechanical polishing process, and then the remaining first substrate 10 and lower pattern BP may be etched by performing the wet etching process. At this time, the wet etching process may be performed for a sufficient time so that the first substrate 10 and lower pattern BP do not remain. In the embodiment, while the first substrate 10 and the lower pattern BP are etched, the source/drain pattern 150 may be protected from being damaged by the etching material by the liner layers 151a and 152a doped with carbon (C) or boron (B).

As shown in FIG. 22 and FIG. 23, a base insulation layer 101 may be formed in the region where the first substrate 10 and the lower pattern BP are removed. In an embodiment, the base insulation layer 101 may include a protruded region 103 in which the base insulation layer 101 protrudes from the upper surface. In the embodiment, the protruded region 103 may be positioned in the region from which the lower pattern BP is removed. The protruded region 103 may surround at least some regions on the sides and lower surfaces of the source/drain pattern 150.

As shown in FIG. 24 and FIG. 25, a first lower recess BRC1 may be formed by etching a portion of the base insulation layer 101. Specifically, a portion of the base insulation layer 101 that overlaps one of the plurality of source/drain patterns 150 in the third direction D3 may be etched by a photo and etching process. By the first lower recess BRC1, some regions of the source/drain pattern 150 may be exposed. In an embodiment, a portion of the source/drain pattern 150 may be etched together with the base insulation layer 101. In the embodiment, the process of forming the first lower recess BRC1 may be performed by a dry etching process, but is not limited thereto.

FIG. 24 and referring to FIG. 25, the width of the first lower recess BRC1 along the first direction D1 and the second direction D2 may be wider than the width of the lower surface of the source/drain pattern 150 along the first direction D1 and the second direction D2. In an embodiment, the process of etching the base insulation layer 101 may be performed using an etching material having higher etch selectivity for the base insulation layer 101 compared to the field insulation layer 105.

As shown in FIG. 26 and FIG. 27, a part of the source/drain pattern 150 exposed by the first lower recess BRC1 may be etched to form a second lower recess BRC2. In the embodiment, the process of forming the second lower recess BRC2 may be performed by a self-aligned contact (SAC) process. In the embodiment, the base insulation layer 101 and the field insulation layer 105 may include an insulating material having an etch selectivity from the source/drain pattern 150. For example, the process of etching a portion of the region of the source/drain pattern 150 exposed by the first lower recess BRC1 may be performed using an etching material having higher etch selectivity for the source/drain pattern 150 compared to the base insulation layer 101 and the field insulation layer 105.

In the embodiment, the process of forming the second lower recess BRC2 may be performed by a dry etching process or a wet etching process.

As shown in FIG. 28 and FIG. 29, a conductive material may be deposited inside the first lower recess BRC1 and the second lower recess BRC2 to form a lower contact electrode 195. First, a barrier pattern 197 is conformally formed on the interior walls of the first lower recess BRC1 and the second lower recess BRC2, and then a lower contact electrode 195 may be formed in the remaining regions except for the regions where the barrier pattern 197 is formed inside the first lower recess BRC1 and the second lower recess BRC2. In the embodiment, a silicide layer 199 may be further formed at the interface of the lower contact electrode 195 and the source/drain pattern 150.

As illustrated in FIG. 30 to 32, a lower wire structure 420 may be formed on the lower surface of the base insulation layer 101. The lower wire structure 420 may include lower conductive patterns 421 and a lower wire insulation layer 422. The lower conductive patterns 421 may be positioned on the lower surface of the base insulation layer 101. The lower conductive patterns 421 may include metal (e.g., copper). The lower conductive patterns 421 may be electrically connected to the lower contact electrode 195. The lower wire insulation layer 412 may include, for example, at least one of silicon oxide (SiO₂), silicon nitride (SiN), silicon oxynitride (SiON), or low dielectric layers.

While this disclosure has been described in connection with what is presently considered to be practical exemplary embodiments, it is to be understood that the disclosure is not limited to the disclosed embodiments, but, on the contrary, is intended to cover various modifications and equivalent arrangements included within the spirit and scope of the appended claims.

What is claimed is:

1. A semiconductor device comprising:
a base insulation layer;
a channel structure positioned on a first surface of the base insulation layer;
a gate structure surrounding the channel structure; and
a first source/drain pattern and a second source/drain pattern arranged spaced apart from each other along a first direction on both sides of the channel structure,
wherein each of the first and second source/drain patterns includes a liner layer and a filling layer on an inner surface of the liner layer,
wherein a portion of the lower and the side surfaces of the first source/drain pattern are covered by the base insulation layer, and
wherein the liner layer includes a carbon-doped silicon germanium.

2. The semiconductor device of claim 1, wherein:
the base insulation layer includes a protruded region protruded from the first surface of the base insulation layer, and
the portion of the lower and side surfaces of the first source/drain pattern are covered by the protruded region.

3. The semiconductor device of claim 2, further comprising:
a lower wire structure on a second surface of the base insulation layer, the second surface facing the first surface of the base insulation layer; and
a lower contact electrode connecting the lower wire structure to the second source/drain pattern,
wherein the lower contact electrode includes a first contact region penetrating the base insulation layer, and a second contact region extending from the upper surface of the first contact region into the interior of the second source/drain pattern.

4. The semiconductor device of claim 3, wherein:
the lower surface of the first source/drain pattern is positioned closer to the lower wire structure than the upper surface of the first contact region.

5. The semiconductor device of claim 3, wherein:
the upper surface of the second contact region is positioned at a level between the lower surface of the gate structure and the upper surface of the first and second source/drain patterns.

6. The semiconductor device of claim 3, wherein:
the second source/drain pattern is positioned apart from the first source/drain pattern in the first direction, and
the second source/drain pattern includes a region that overlaps the first contact region in the first direction.

7. The semiconductor device of claim 3, wherein:
the width of the first contact region along the first direction is wider than the width of the first source/drain pattern along the first direction.

8. The semiconductor device of claim 3, wherein:
the width of the second contact region along the first direction is equal to or narrower than the width of the first source/drain pattern along the first direction.

9. The semiconductor device of claim 1, wherein:
the first and second source/drain patterns are doped by an N-type impurity.

10. The semiconductor device of claim 1, wherein:
the distance from the bottom surface of the gate structure to the lower surface of the first source/drain pattern is greater than or equal to 20 nm and less than or equal to 100 nm.

11. The semiconductor device of claim 2, further comprising:
a field insulation layer positioned on both sides of the protruded region,
wherein, in the region of the first source/drain pattern positioned at a level lower than the lower surface of the gate structure, the liner layer is positioned between the field insulation layer and the filling layer.

12. The semiconductor device of claim 1, wherein:
the base insulation layer includes an insulating material having an etch selectivity from the first and second source/drain patterns.

13. The semiconductor device of claim 3, further comprising:
a silicide layer positioned between the second contact region and the second source/drain pattern.

14. A semiconductor device comprising:
a base insulation layer including a first surface and a second surface facing the first surface;
a channel structure positioned on the first surface of the base insulation layer;
a gate structure surrounding the channel structure;
a first source/drain pattern and a second source/drain pattern each positioned on both sides of the channel structure, the first source/drain pattern extending inside the base insulation layer;
a lower wire structure positioned on the second surface of the base insulation layer; and
a lower contact electrode connecting the second source/drain pattern and the lower wire structure,
wherein the lower contact electrode includes a first contact region extending into the interior of the base insulation layer, and a second contact region extending from the upper surface of the first contact region into the interior of the second source/drain pattern, and
the upper surface of the first contact region is positioned between the lower surface of the gate structure and the lower surface of the first source/drain pattern.

15. The semiconductor device of claim 14, wherein:
the first source/drain pattern includes a liner layer conformally positioned along the interface with the channel structure and the interface with the gate structure and the interface with the base insulation layer, and a filling layer on an inner surface of the liner layer, and
the liner layer includes a carbon-doped silicon germanium.

16. The semiconductor device of claim 14, wherein:
the base insulation layer includes a protruded region protruded from the first surface and surrounding the side and lower surfaces of the first source/drain pattern.

17. The semiconductor device of claim 14, wherein:
the upper surface of the second contact region is positioned between the lower surface of the gate structure and the upper surface of the second source/drain pattern.

18. The semiconductor device of claim 15, further comprising:
a field insulation layer on both sides of the protruded region,
wherein, in the region of the first source/drain pattern positioned at a level lower than the lower surface of the gate structure, the liner layer is positioned between the field insulation layer and the filling layer.

19. A semiconductor device comprising:
a base insulation layer;
a channel structure positioned above the base insulation layer;
a gate structure surrounding the channel structure;
source/drain patterns including a first source/drain pattern and a second source/drain pattern positioned on both sides of the channel structure;
a lower wire structure positioned above the lower surface of the base insulation layer; and
a lower contact electrode connecting the second source/drain pattern and the lower wire structure,
an upper wire structure positioned above the source/drain patterns, and
an upper contact electrode connecting the first source/drain pattern and the upper wire structure,
wherein the lower contact electrode includes a first contact region extending into the interior of the base insulation layer, and a second contact region extending from the upper surface of the first contact region into the interior of the second source/drain pattern, and
the upper surface of the first contact region is positioned between the lower surface of the gate structure and the lower surface of the first source/drain pattern.

20. The semiconductor device of claim 19, wherein:
the first source/drain pattern and the second source/drain pattern include a liner layer conformally positioned along the interface with the channel structure and the interface with the gate structure, and a filling layer on the inner surface of the liner layer,
the liner layer includes a carbon-doped silicon germanium.
